(19) United States
(12) Patent Application Publication
(10) Pub. No.: US 2024/0349543 A1
(43) Pub. Date: Oct. 17, 2024

(54) DISPLAY DEVICE

(71) Applicant: Japan Display Inc., Tokyo (JP)

(72) Inventor: Kaichi FUKUDA, Tokyo (JP)

(73) Assignee: Japan Display Inc., Tokyo (JP)

(21) Appl. No.: 18/751,946

(22) Filed: Jun. 24, 2024

Related U.S. Application Data
(63) Continuation of application No. PCT/JP2022/043032, filed on Nov. 21, 2022.

(30) Foreign Application Priority Data
Dec. 24, 2021 (JP) 2021-211107

(51) Int. Cl. H10K 59/122; H10K 59/12

(52) U.S. Cl. CPC H10K 59/122; H10K 59/1201

(57) ABSTRACT

A display device includes a first pixel electrode on an insulating surface, a second pixel electrode spaced apart from the first pixel electrode in a first direction, a third pixel electrode spaced apart from the first pixel electrode in a second direction, an organic insulating layer overlapping a part of the first pixel electrode and a part of the second pixel electrode in the first direction, a first common layer on the first pixel electrode, the second pixel electrode, the third pixel electrode, and the organic insulating layer, a first light emitting layer on the first common layer and continuously overlapping the first pixel electrode, the second pixel electrode, and the organic insulating layer, a second light emitting layer on the first pixel electrode and overlapping the third light emitting layer, and a counter electrode on the first light emitting layer and the second light emitting layer.

### CROSS-REFERENCE TO RELATED APPLICATIONS

This application is a Continuation of International Patent Application No. PCT/JP2022/043032, filed on Nov. 21, 2022, which claims the benefit of priority to Japanese Patent Application No. 2021-211107, filed on Dec. 24, 2021, the entire contents of which are incorporated herein by reference.

### FIELD

An embodiment of the present invention relates to a display device and a method for manufacturing the display device.

### BACKGROUND

an organic EL display device (Organic Electroluminescence Display) in which an organic electroluminescent material (organic EL material) is used as a light emitting device (organic EL device) of a display portion (for example, Japanese Laid-Open Patent Publication No. 2011-9169) has been conventionally known as a display device. In recent years, there have been increasing demands for higher definition in organic EL displays.

### SUMMARY

A display device according to an embodiment of the present invention includes a first pixel electrode arranged on an insulating surface, a second pixel electrode spaced apart from the first pixel electrode in a first direction, a third pixel electrode spaced apart from the first pixel electrode in a second direction intersecting the first direction, an organic insulating layer overlapping a part of the first pixel electrode and a part of the second pixel electrode in the first direction, a first common layer arranged on the first pixel electrode, the second pixel electrode, the third pixel electrode, and the organic insulating layer, a first light emitting layer arranged on the first common layer and continuously arranged overlapping the first pixel electrode, the second pixel electrode, and the organic insulating layer, a second light emitting layer arranged on the first pixel electrode and arranged overlapping the third light emitting layer, and a counter electrode arranged on the first light emitting layer and the second light emitting layer, wherein the first common layer includes a first region overlapping the first pixel electrode, a second region arranged between the first pixel electrode and the third pixel electrode, and a third region overlapping the third pixel electrode, and the second region is spaced apart from each of the first region and third region.

### BRIEF DESCRIPTION OF DRAWINGS

FIG. 1 is a schematic plan view of a display device according to an embodiment of the present invention.

FIG. 2 is an enlarged view of a pixel layout in a plan view of the display device.

FIG. 3 is a cross-sectional view of the display device shown in FIG. 2 along a line A1-A2.

FIG. 4 is a cross-sectional view of the display device shown in FIG. 2 along a line B1-B2.

FIG. 5 is a cross-sectional view for explaining a method for manufacturing a display device according to an embodiment of the present invention.

FIG. 6 is a cross-sectional view for explaining a method for manufacturing a display device according to an embodiment of the present invention.

FIG. 7 is a plan view for explaining a method for manufacturing a display device according to an embodiment of the present invention.

FIG. 8 is a cross-sectional view for explaining a method for manufacturing a display device according to an embodiment of the present invention.

FIG. 9 is an enlarged view of a part of the cross-sectional view shown in FIG. 8.

FIG. 10 is a cross-sectional view for explaining a method for manufacturing a display device according to an embodiment of the present invention.

FIG. 11 is a cross-sectional view for explaining a method for manufacturing a display device according to an embodiment of the present invention.

FIG. 12 is an enlarged view of a pixel layout in a plan view of a display device according to an embodiment of the present invention.

FIG. 13 is a cross-sectional view of the display device shown in FIG. 12 along a line A1-A2.

FIG. 14 is a cross-sectional view of the display device shown in FIG. 12 along a line B1-B2.

FIG. 15 is an enlarged view of a part of the cross-sectional view shown in FIG. 14.

FIG. 16 is an enlarged view of a pixel layout in a plan view of a display device according to an embodiment of the present invention.

FIG. 17 is a cross-sectional view of the display device shown in FIG. 16 along a line A1-A2.

FIG. 18 is an enlarged view of a pixel layout in a plan view of the display device.

FIG. 19 is a cross-sectional view of the display device shown in FIG. 18 along a line C1-C2.

FIG. 20 is a cross-sectional view of the display device shown in FIG. 18 along a line D1-D2.

FIG. 21 is an enlarged view of a pixel layout in a plan view of the display device.

FIG. 22 is a cross-sectional view of the display device shown in FIG. 21 along a line E1-E2.

FIG. 23 is a cross-sectional view of the display device shown in FIG. 21 along a line F1-F2.

FIG. 24 is a cross-sectional view of a pixel in a conventional display device.

### DESCRIPTION OF EMBODIMENTS

In an organic EL display device, organic EL layers are formed by vapor deposition using a metal mask. At this time, in the case where the vapor deposited films of the respective colors overlap each other, a lateral leakage current may flow between pixels of different colors. In an EL display device, a lateral leakage current may cause neighboring pixels to emit light, thereby deteriorating display properties of the EL display device.

If a distance between vapor deposition patterns of the respective colors is increased to prevent the lateral leakage current, pixel aperture ratio decreases. As described above, it is difficult to achieve both a high aperture ratio of pixels and an improvement of display characteristics.

Therefore, an embodiment of the present invention provides a display device in which a lateral leakage current between pixels of different colors is suppressed.

Hereinafter, embodiments of the present invention will be described with reference to the drawings and the like. However, the present invention can be implemented in various aspects without departing from the gist thereof, and is not to be construed as being limited to the description of the embodiments exemplified below. Further, in order to clarify the description with respect to the drawings, although the width, the film thickness, the shape, and the like of each part may be schematically represented in comparison with the actual embodiment, the schematic drawings are merely examples, and do not limit the interpretation of the present invention. Further, in the present specification and the drawings, the same or similar elements as those described with respect to the drawings already described are denoted by the same reference signs, and any redundant description may be omitted.

In the present invention, in the case where a single film is processed to form a plurality of films, the plurality of films may have different functions and roles. However, the plurality of films is derived from a film formed as the same layer in the same process, and has the same layer structure and the same material. Therefore, the plurality of films is defined as being present in the same layer.

In addition, in this specification, expressions such as “upper” and “lower” in describing the drawings represent relative positional relationships between a structure of interest and other structures. In the present specification, in a side view, a direction from an insulating surface described later to a light emitting device is defined as “upper”, and a reverse direction thereof is defined as “lower.” In the present specification and claims, an expression “above” in describing a manner of placing another structure on a structure includes both the case of placing another structure directly on a structure and the case of placing another structure above a structure via further another structure, unless otherwise specified.

### First Embodiment

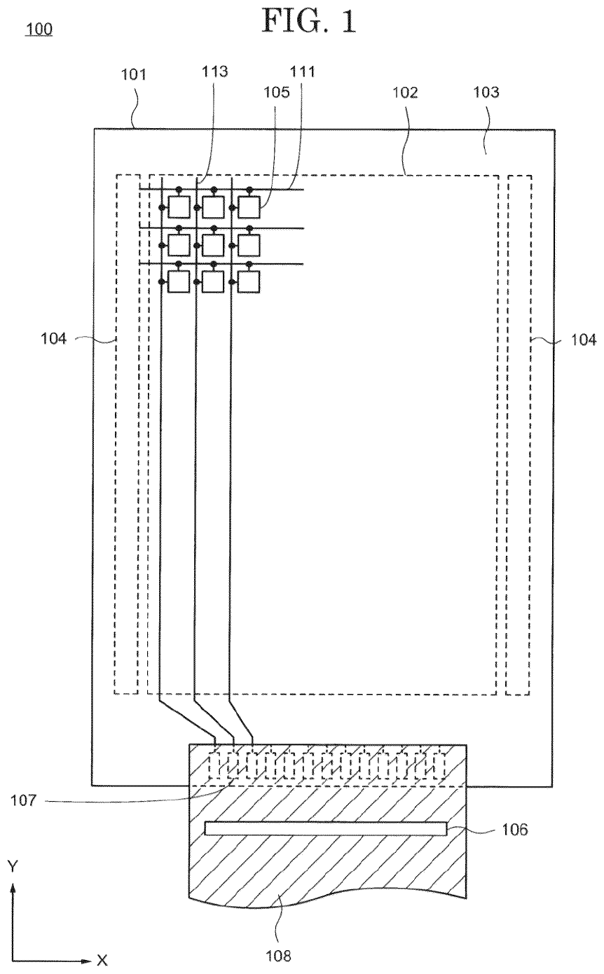

A display device according to an embodiment of the present invention will be described with reference to FIG. 1 to FIG. 11.

FIG. 1 is a schematic diagram showing a configuration of a display device 100 according to an embodiment of the present invention, and shows a schematic configuration of the display device 100 in a plan view. In this specification, a state in which the display device 100 is viewed from a direction perpendicular to a screen (display region) is referred to as a “plan view”.

As shown in FIG. 1, the display device 100 includes a display region 102 formed on an insulating surface, a scan line driver circuit 104, a driver IC 106, and a terminal part in which a plurality of terminals 107 are arranged. In the display region 102, a light emitting device having an organic layer including a light emitting layer is arranged. In addition, a peripheral region 103 surrounds a periphery of the display region 102. The driver IC 106 functions as a control unit that provides signals to the scan line driver circuit 104 and a data line driver circuit. In the data line driver circuit, a sampling switch or the like may be arranged on a substrate 101 in addition to the driver IC 106. Further, although the driver IC 106 is arranged on a flexible print circuit 108 (Flexible Print Circuit: FPC), the driver IC 106 may be arranged on the substrate 101. The flexible print circuit 108 is connected to the plurality of terminals 107 arranged in the peripheral region 103.

Here, the insulating surface is a surface of the substrate 101. The substrate 101 supports respective layers, such as an insulating layer and a conductive layer, arranged on the surface thereof. In addition, the substrate 101 itself is made of an insulating material and may have an insulating surface, or an insulating surface may be formed by additionally forming an insulating film on the substrate 101. A material of the substrate 101 and a material for forming the insulating film are not particularly limited as long as the insulating surface can be obtained. In addition, even if the insulating film is not arranged directly on the substrate 101, the insulating surface can be obtained as long as the insulating film is arranged above the substrate 101.

In the display region 102 shown in FIG. 1, a plurality of pixels 105 is arranged in a matrix in a direction X and a direction Y. In this specification and the like, a pixel refers to a minimum unit that enables display of a desired color in the display region 102. Each of the pixels 105 includes a pixel circuit and light emitting devices electrically connected to the pixel circuit. The light emitting devices include a pixel electrode, an organic layer (light emitting portion) including a light emitting layer stacked on the pixel electrode, and a counter electrode. The light emitting devices included in the pixels 105 emit red, green, or blue-light. In addition, an emission peak wavelength of the blue-light emitting device is 460 nm or more and 500 nm or less. An emission peak wavelength of the red-light emitting device is 610 nm or more and 780 nm or less. An emission peak wavelength of the green-light emitting device is 500 nm or more and 570 nm or less. In addition, the color emitted by the light emitting device is not limited to the above, and may be at least more than one color. In this specification and the like, in the case where the colors emitted by the light emitting devices are described separately, a pixel 105R for emitting red light, a pixel 105G for emitting green-light, and a pixel 105B for emitting blue-light are shown. Constituent elements included in the pixels 105R, 105G, and 105B are similarly distinguished from each other by the signs R, G, and B. In addition, in the case where the respective pixels 105R, 105G, and 105B are not distinguished from each other, they are simply referred to as the pixels 105. Further, the same applies to each constituent elements of the pixels 105R, 105G, and 105B.

The pixel 105 is electrically connected to a scanning line 111 and a data line 113. The pixel 105 is electrically connected to a power supply line (not shown). The scanning line 111 extends along the direction X and is electrically connected to the scanning line driver circuit 104. The data line 113 extends along the direction Y and is electrically connected to the driver IC 106. In addition, the driver IC 106 outputs a scanning signal to the scanning line 111 via the scanning line driver circuit 104. The driver IC 106 outputs a data signal corresponding to image data to the data line 113. A screen display corresponding to the image data can be performed by inputting the scanning signal and the data signal to the pixel circuit included in each of the pixels 105. The pixel circuit includes a plurality of transistors. Typically, a thin film transistor (Thin Film Transistor: TFT) can be used as the transistor. However, the present invention is not limited to the thin film transistor, and any device having a current control function may be used.

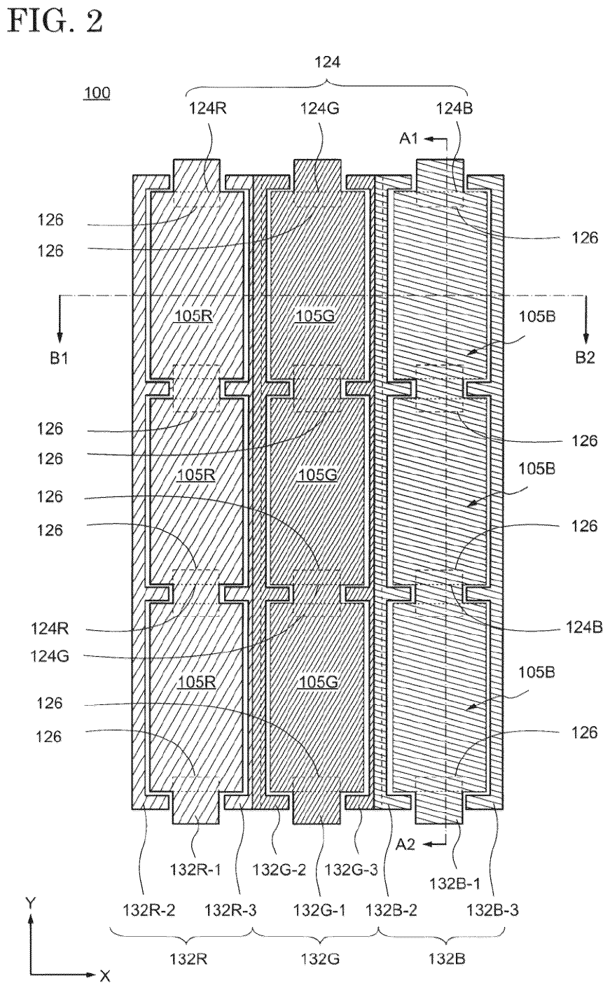

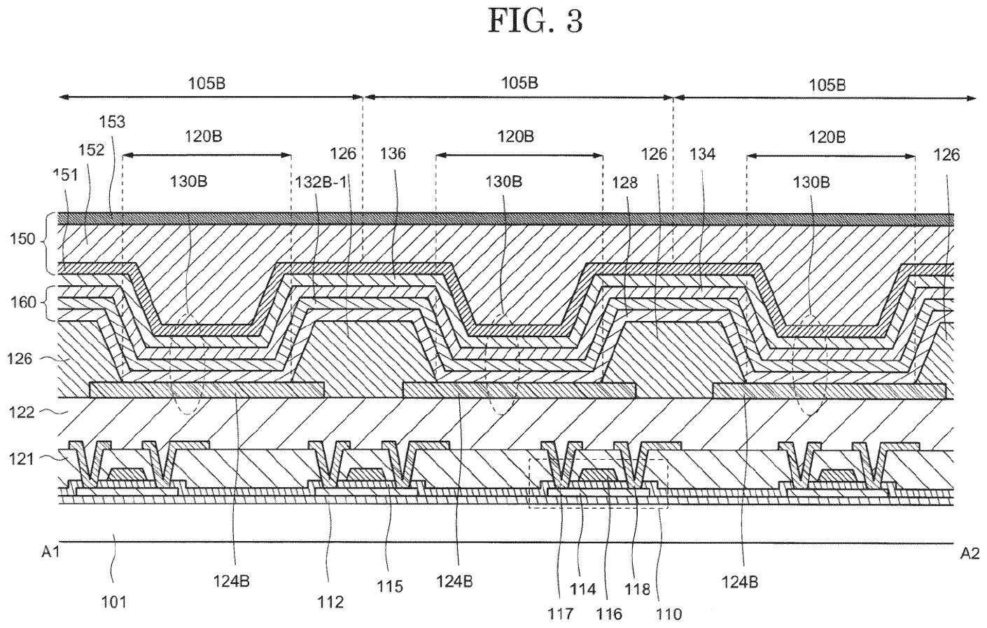

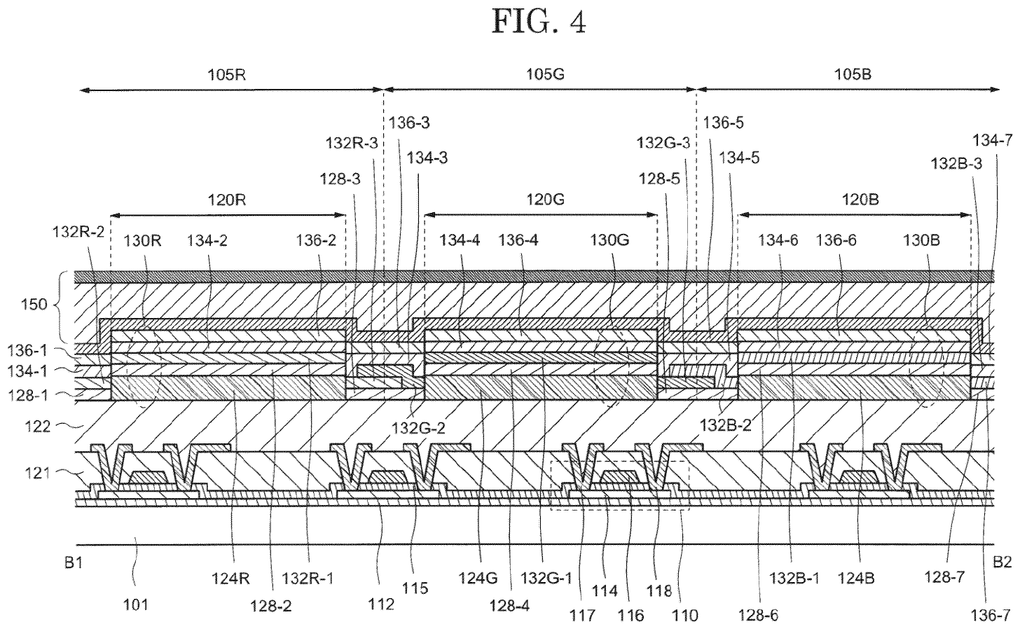

FIG. 2 is an enlarged view of a pixel layout in a plan view of the display device 100, and FIG. 3 is a cross-sectional view of the pixel layout shown in FIG. 2 along a line A1-A2. FIG. 4 is a cross-sectional view of the pixel layout shown in FIG. 2 along a line B1-B2. In the present embodiment, a configuration of a top emission type display device will be described.

FIG. 2 shows a region in which the pixel 105R having the red-light emitting device, the pixel 105G having the green-light emitting device, and the pixel 105B having the blue-light emitting device are arranged. The pixel 105R, the pixel 105G, and the pixel 105B are arranged side by side in the direction X. Each of a plurality of pixels 105R, a plurality of pixels 105G, and a plurality of pixels 105B is arranged in a stripe shape along the direction Y.

In FIG. 2, a region surrounded by a short-wave line is a region in which a pixel electrode 124 is arranged. A shape of the pixel electrode 124 in a plan view is, for example, a rectangle. A plurality of pixel electrodes 124 is arranged in a matrix in the direction X and the direction Y. In FIG. 2, pixel electrodes 124R, 124G, and 124B are arranged side by side in the direction X.

In FIG. 2, a region surrounded by a broken line is a region in which an organic insulating layer 126 is arranged. The organic insulating layer 126 is also referred to as a partition wall or a bank. A shape of the organic insulating layer 126 in a plan view is rectangular. The organic insulating layer 126 is arranged so as to cover end portions of two-pixel electrodes 124 adjacent to each other in the direction Y. The organic insulating layer 126 is not arranged above two-pixel electrodes 124 adjacent to each other in the direction X. That is, the organic insulating layer 126 is arranged in a region where the light emitting devices of the same color are adjacent to each other, and the organic insulating layer 126 is not arranged in a region where the light emitting devices of different colors are adjacent to each other. In FIG. 2, although a length (width) of the organic insulating layer 126 in the direction X in a plan view is smaller than a length of the pixel electrode 124 in the direction X, the present invention is not limited thereto. The length of the organic insulating layer 126 in the direction X may be substantially the same as the length (width) of the pixel electrode 124 in the direction X.

In FIG. 2, a region indicated by a solid line is a region in which light emitting layers 132R, 132G, and 132B are arranged. The light emitting layer 132R has light emitting layers 132R-1 to 132R-3. In the present specification and the like, a plurality of layers formed in the same process is denoted separately by numbers such as −1, −2, −3, and the like. In addition, in the case where a plurality of layers formed in the same process are described without being distinguished from each other, numbers may not be given in some cases. The light emitting layers 132R-1 to 132R-3 are separated from each other. The light emitting layer 132R-1 is arranged above the plurality of pixel electrodes 124R adjacent to each other in the direction Y. The light emitting layer 132R-2 is arranged adjacent to the pixel electrode 124R in the direction X. The light emitting layer 132R-3 is arranged between the pixel electrodes 124R and the pixel electrodes 124G. That is, the light emitting layers 132R-1 to 132R-3 extend along the direction Y and are separated in the direction X. The light emitting layer 132R has a region extending along the direction Y on the pixel electrode 124 and a region extending along the direction Y between two-pixel electrodes 124 adjacent to each other. The light emitting layer 132G has light emitting layers 132G-1 to 132G-3. The light emitting layer 132G-1 is arranged on the plurality of pixel electrodes 124G adjacent to each other in the direction Y. The light emitting layer 132G-2 is arranged between the pixel electrodes 124R and the pixel electrodes 124G. The light emitting layer 132G-3 is arranged between the pixel electrodes 124G and the pixel electrodes 124B. Light emitting layers 132B-1 to 132B-3 are separated from each other. In addition, the light emitting layer 132B-1 is arranged on the plurality of pixel electrodes 124B that are adjacent to each other in the direction Y. The light emitting layer 132B-2 is arranged between the pixel electrodes 124G and the pixel electrodes 124B. The light emitting layer 132B-3 is arranged adjacent to the pixel electrode 124B in the direction X. The light emitting layer 132R-3 and the light emitting layer 132G-2 overlap each other, and the light emitting layer 132G-3 and the light emitting layer 132B-2 overlap each other.

Here, a length (width) of the light emitting layer 132R-1 in the direction X is substantially the same as a length (width) of the pixel electrodes 124R in the direction X. In addition, a length (width) of the light emitting layer 132G-1 in the direction X is substantially the same as the length (width) of the pixel electrode 124R in the direction X. In addition, a length (width) of the light emitting layer 132B-1 in the direction X is substantially the same as the length (width) of the pixel electrode 124R in the direction X. When a light emitting layer 132 is formed by a vapor deposition method, a light emitting material is less likely to be attached to an upper end portion of the pixel electrode 124. Therefore, the light emitting layer 132 is separated into a region overlapping the pixel electrode 124 and the organic insulating layer 126 and a region adjacent to the pixel electrode 124. As a result, the length of the light emitting layer 132R-1 in the direction X is substantially the same as the length of the pixel electrode 124 in the direction X.

In FIG. 2, a region where the pixel electrode 124 and the light emitting layer 132 overlap corresponds to a light emitting region when a light emitting device 130 emits light.

FIG. 3 is a cross-sectional view of the plurality of pixels 105B. The pixel 105B is arranged with a light emitting device 130B. In FIG. 3, a light emitting region of the light emitting device 130 is shown as a light emitting region 120.

On the substrate 101, a plurality of transistors 110 are arranged via an insulating film 112. The plurality of transistors 110 constitutes a pixel circuit. The transistor 110 includes at least a semiconductor layer 114, a gate insulating film 115, and a gate electrode 116. An interlayer insulating film 121 is arranged on the transistor 110. Source electrodes or drain electrodes 117 and 118 are respectively arranged on the interlayer insulating film 121. The source electrodes or the drain electrodes 117 and 118 are respectively connected to the semiconductor layer 114 via a contact hole arranged in the interlayer insulating film 121. An insulating film 122 is arranged on the interlayer insulating film 121. The insulating film 122 can reduce unevenness caused by the transistor 110 and the source electrodes or the drain electrodes 117 and 118. The plurality of transistors 110 arranged on the substrate 101, and the interlayer insulating film 121 and the insulating film 122 arranged on the transistor 110 are formed by a known material or method. In addition, in FIG. 4 and subsequent figures, a configuration of a pixel circuit arranged below the insulating film 122 is the same as that in FIG. 3, and thus a detailed description thereof is omitted.

The pluralities of pixel electrodes 124B are arranged on the insulating film 122. Although not shown, the pixel electrodes 124B are electrically connected to the transistors 110 included in the pixel circuit. In the present embodiment, the pixel electrode 124B functions as an anode. For example, a highly reflective metallic film such as silver is used as the pixel electrode 124B. Alternatively, a highly work functional transparent conductive layer such as an indium oxide-based transparent conductive layer (for example, ITO: Indium Tin Oxide) or a zinc oxide-based transparent conductive layer (for example, IZO: Indium Zinc Oxide and ZnO: Zinc Oxide) may be used as the pixel electrode 124B. In the case where the pixel electrode 124 is formed in a laminated structure, a laminated structure of a transparent conductive layer, a metal film, and a transparent conductive layer is used.

The organic insulating layers 126 are arranged on the insulating film 122 so as to cover the end portions of the pixel electrodes 124B. In other words, the organic insulating layers 126 are arranged at the ends of the two-pixel electrodes 124B adjacent to each other. The organic insulating layers 126 are arranged so that an organic layer 160 including the light emitting layer 132B arranged on the plurality of pixel electrodes 124B is continuously arranged in the plurality of adjacent pixels 105B without being cut. Therefore, the organic insulating layers 126 are preferably gently inclined. In addition, cross sections of upper end portions of the organic insulating layers 126 are preferably rounded. As a result, it is possible to prevent the organic layer 160 from being stepped off at the upper end portions of the organic insulating layers 126. A known organic resin material such as a polyimide-based, a polyamide-based, an acrylic-based, an epoxy-based, or a siloxane-based can be used as the organic insulating layer 126. In addition, the organic insulating layer 126 is not arranged between the pixel electrodes 124B and the pixel electrodes 124G. Also, the organic insulating layer 126 is not arranged between the pixel electrodes 124G and the pixel electrodes 124R. That is, the organic insulating layer 126 is arranged in the case where the light emitting devices 130 of the same color are continuously arranged in the adjacent pixel electrodes 124.

A common layer 128 is arranged on the plurality of pixel electrodes 124B and the plurality of organic insulating layers 126. The common layer 128 is commonly arranged over a plurality of light emitting devices 130B. The common layer 128 includes at least one of a hole transport layer and a hole injection layer.

The light emitting layer 132B is arranged on the common layer 128. The light emitting layer 132B-1 is commonly arranged over the plurality of light emitting devices 130B.

A common layer 134 is arranged on the light emitting layer 132B-1. The common layer 134 is commonly arranged over the plurality of light emitting devices 130B. The common layer 134 includes at least one of an electron transport layer and an electron injection layer. In the present embodiment, the organic layer 160 includes the common layer 128, the light emitting layer 132, and the common layer 134.

A counter electrode 136 is arranged on the common layer 134. The counter electrode 136 is commonly arranged over the plurality of light emitting devices 130B. A light transmitting electrode is used as the counter electrode 136. A Mg Ag thin film or transparent conductive layer (ITO or IZO) is used as the counter electrode 136.

A sealing film 150 is arranged on the counter electrode 136. The sealing film 150 includes an inorganic insulating film 151, an organic insulating film 152, and an inorganic insulating film 153. In the case where moisture enters from the outside, the inorganic insulating film 151 and the inorganic insulating film 153 can prevent moisture from entering the light emitting device 130. Further, by providing the organic insulating film 152 between the inorganic insulating film 151 and the inorganic insulating film 153, cracking of the sealing film 150 can be suppressed. In addition, although not shown, it is preferable that the inorganic insulating film 151 and the inorganic insulating film 153 are in contact with each other in the peripheral region 103 because the sealing function against moisture is improved.

FIG. 4 is a cross-sectional view of the pixels 105R, 105G, and 105B. As shown in FIG. 4, the pixel 105R is arranged with a light emitting device 130R, the pixel 105G is arranged with a light emitting device 130G, and the pixel 105B is arranged with a light emitting device 130B. In FIG. 4, light emitting regions of the light emitting devices 130R, 130G, and 130B are shown as light emitting regions 120R, 120G, and 120B.

The pixel electrodes 124R, 124G, and 124B are arranged on the insulating film 122. The common layer 128 is arranged on the pixel electrodes 124R, 124G, and 124B. In FIG. 4, the common layer 128 is separated by upper end portions of the pixel electrodes 124R, 124G, and 124B. Therefore, the common layer 128 includes common layers 128-1 to 128-7. The common layer 128-2 is arranged on the pixel electrode 124R, the common layer 128-4 is arranged on the pixel electrode 124G, and the common layer 128-6 is arranged on the pixel electrode 124B. The common layer 128-1 is arranged adjacent to the pixel electrode 124R in the direction X. In addition, the common layer 128-3 is arranged between the pixel electrode 124R and the pixel electrode 124G. The common layer 128-5 is arranged between the pixel electrode 124G and the pixel electrode 124B. In addition, the common layer 128-7 is arranged adjacent to the pixel electrode 124B in the direction X.

Here, a film thickness of the pixel electrode 124 is larger than a film thickness of the common layer 128. Therefore, when the common layer 128 is formed on the pixel electrode 124 by vapor deposition, the common layer 128 is less likely to be attached to a side surface of the pixel electrode 124. As a result, the common layer 128 can be separated at the upper end portion of the pixel electrode 124. The film thickness of the pixel electrode 124 is, for example, 60 nm or more and 350 nm or less. The thickness of the common layer 128 is, for example, 30 nm or more and 150 nm or less, and is less than the thickness of the pixel electrode 124. For optical adjustment of the light emitting device 130, the thickness of the common layer 128 may be different depending on an emission color of the light emitting device 130. That is, a film thickness of the common layer 128-2, a film thickness of the common layer 128-4, and a film thickness of the common layer 128-6 may be different from each other. Even in this case, film thicknesses of the pixel electrodes 124R, 124G, and 124B are preferably larger than the film thicknesses of the common layers 128-2, 128-4, and 128-6.

In FIG. 4 and the configurations described above, examples are shown in which the total thickness of the common layer 128 is smaller than that of the pixel electrode 124. Although not particularly shown, the common layer 128 includes a hole injection layer arranged in contact with the pixel electrode 124 and a hole transport layer stacked thereon. In this case, if a film thickness of the hole injection layer is smaller than the film thickness of the pixel electrode 124, a total thickness of the common layer 128 including a stack of the hole injection layer and the hole transport layer may exceed the pixel electrode 124. Of course, it is desirable that the common layer 128 be divided over the entire layer, as described above, however, in the common layer 128, the hole injection layer may have relatively low resistance due to an action of dopants added to improve hole injection efficiency from the pixel electrode 124. Therefore, a leakage current in a lateral direction can be reduced by dividing the layer by the upper end portion of the pixel electrode 124. In this configuration, the film thickness of the pixel electrode 124 is, for example, 60 nm or more and 350 nm or less. The thickness of the common layer 128 may be, for example, 100 nm or more and 150 nm or less and less than the film thickness of the pixel electrode 124 described above, wherein the thickness of the hole injecting layer which is arranged in contact with the pixel electrode 124 may be, for example, 10 nm or more and 30 nm or less.

The light emitting layers 132R-1 to 132R-3, the light emitting layers 132G-1 to 132G-3, and the light emitting layers 132B-1 to 132B-3 are arranged on the common layer 128. The light emitting layer 132R-1 is arranged on the common layer 128-2, the light emitting layer 132G-1 is arranged on the common layer 128-4, and the light emitting layer 132B-1 is arranged on the common layer 128-6. The light emitting layer 132R-2 is arranged on the common layer 128-1, the light emitting layer 132R-3 and the light emitting layer 132G-2 are arranged on the common layer 128-3, and the light emitting layer 132G-3 and the light emitting layer 132B-2 are arranged on the common layer 128-5.

Here, a sum of the film thickness of the pixel electrode 124 and the film thickness of the common layer 128 is larger than a film thickness of the light emitting layer 132. Therefore, when the light emitting layer 132 is formed on the common layer 128 by vapor deposition, the light emitting layer 132 is less likely to be attached to the side surface of the pixel electrode 124 and a side surface of the common layer 128. As a result, the light emitting layer 132 can be separated at an upper end portion of the common layer. The thickness of the light emitting layers 132 is 10 nm or more and 50 nm or less. In addition, the film thickness of the light emitting layer 132 may be different depending on the emission color of the light emitting device 130. Even in this case, the sum of the thickness of the pixel electrode 124 and the thickness of the common layer 128 is preferably larger than the thickness of the light emitting layer 132.

The common layer 134 is arranged on the light emitting layers 132R, 132G, and 132B. The common layer 134 is separated by the light emitting layers 132R-1, 132G-1, and 132B-1. Therefore, the common layer 134 includes common layers 134-1 to 134-7. The common layer 134-2 is arranged on the light emitting layer 132R-1, the common layer 134-4 is arranged on the light emitting layer 132G-1, and the common layer 134-6 is arranged on the light emitting layer 132B-1. The common layer 134-1 is arranged adjacent to the pixel electrode 124R. In addition, the common layer 134-3 is arranged between the pixel electrode 124R and the pixel electrode 124G. The common layer 134-5 is arranged between the pixel electrode 124G and the pixel electrode 124B. In addition, the common layer 134-7 is arranged adjacent to the pixel electrode 124B in the direction X.

The counter electrode 136 is arranged on the common layer 134. The counter electrodes 136 are separated by common layers 134-2, 134-4, and 134-6. Therefore, the counter electrode 136 includes counter electrodes 136-1 to 136-7. The counter electrode 136-2 is arranged on the common layer 134-2, the counter electrode 136-4 is arranged on the common layer 134-4, and the counter electrode 136-6 is arranged on the common layer 134-6. The counter electrode 136-1 is arranged adjacent to the pixel electrode 124R. In addition, the counter electrode 136-3 is arranged between the pixel electrode 124R and the pixel electrode 124G. The counter electrode 136-5 is arranged between the pixel electrode 124G and the pixel electrode 124B. The counter electrode 136-7 is arranged adjacent to the pixel electrode 124B in the direction X.

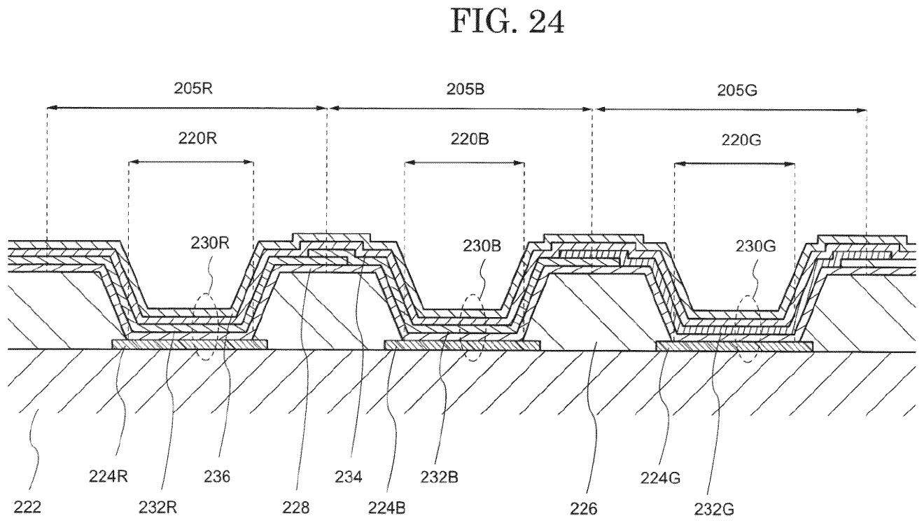

Hereinafter, a mechanism in which a light emitting layer emits light in an unintended region in a neighboring pixel due to a lateral leakage current (leakage current in the direction X) in an EL displaying device will be described with reference to FIG. 24. In FIG. 24, a configuration of a pixel circuit arranged below an insulating film 222 is omitted.

FIG. 24 is a cross-sectional view of pixels 205R, 205G, and 205B in a conventional display device. On the insulating film 222, a light emitting device 230R is arranged in the pixel 205R, a light emitting device 230G is arranged in the pixel 205G, and a light emitting device 230B is arranged in the pixel 205B. The light emitting device 230R includes at least a pixel electrode 224R, a light emitting layer 232R, and a counter electrode 236. The light emitting device 230G includes at least a pixel electrode 224G, a light emitting layer 232G, and the counter electrode 236. The light emitting device 230B includes at least a pixel electrode 224B, a light emitting layer 232B, and the counter electrode 236. A common layer 228 is arranged between the pixel electrodes 224R, 224G, and 224B and the light emitting layers 232R, 232G, and 232B. A common layer 234 is arranged between the light emitting layers 232R, 232G, and 232B and the counter electrode 236. The common layers 228 and 234 are arranged in common over the light emitting devices 230R, 230G, and 230B (over the displaying region). In FIG. 24, the pixel electrodes 224R, 224G, and 224B are anodes, and the counter electrode 236 is a cathode. Therefore, the common layer 228 includes at least one of a hole transport layer and a hole injection layer, and the common layer 234 includes at least one of an electron transport layer and an electron injection layer.

End portions of the pixel electrodes 224R, 224G, and 224B are covered with an insulating layer 226. In addition, the insulating layers 226 are arranged with openings 220R, 220G, and 220B so as to expose the pixel electrodes 224R, 224G, and 224B. The openings 220R, 220G, and 220B correspond to light emitting regions in light emitting devices.

On the insulating layer 226, the light emitting layer 232B and the light emitting layer 232R are arranged on the common layer 228. A portion of the light emitting layer 232B overlaps a portion of the light emitting layer 232R. Generally, a light emission starts voltage of the light emitting layer 232B is larger than light emission initialization voltage of a light emitting layer 228R and the light emitting layer 232G. Therefore, when the light emitting device 230B is caused to emit light, a large voltage is applied to the light emitting layer 232B, so that holes in the common layer 228 move laterally from the pixel 205B toward the pixel 205R and the pixel 205G. In the case where the light emitting layer 232B shows a hole transporting property, the hole passes through a thickness of the light emitting layer 232B. Therefore, the light emitting layer 232R and the light emitting layer 232G emit light at an end portion of the light emitting layer 232R. Alternatively, in the case where the light emitting layer 232B shows an electron transporting property, the holes do not pass in a thickness direction of the light emitting layer 232B but move in a lateral direction. Therefore, the light emitting layer 232R emits light in a vicinity of an end portion of the light emitting layer 232B. In addition, the light emission initialization voltage of the light emitting layer 232R and the light emission initialization voltage of the light emitting layer 232G are approximately the same. Therefore, even if the light emitting device 230G is caused to emit light, the holes in the common layer 228 are prevented from moving laterally from the pixel 205G to the pixel 205R and the pixel 205B. Therefore, in a region where an end portion of the light emitting layer 232G and the end portion of the light emitting layer 232R overlap each other, the end portion of the light emitting layer 232G and the end portion of the light emitting layer 232R are unlikely to emit light.

As described above, when the adjacent light emitting layers 232 overlap each other on the insulating layer 226, a leakage current may flow between pixels of different colors. In an EL display device, a lateral leakage current may cause adjacent pixels to emit light, thereby deteriorating display properties of the EL display device.

In order to suppress unintended light emission in adjacent pixels, regions in which the light emitting layer 232 are arranged may be formed so as not to overlap each other. However, in order to form the regions in which the light emitting layers 232 are arranged so as not to overlap each other, the openings 220R, 220G, and 220B need to be formed sufficiently apart from each other, resulting in a reduction in definition.

Therefore, in the display device 100 according to an embodiment of the present disclosure, at least the common layer 128 is separated so as to extend in the direction Y between the pixels 105R, 105G, and 105B of different colors. Specifically, the common layer 128 is separated by using the covering properties of an organic material in the end portion of the pixel electrode 124. As a result, the common layer 128 is separated between the different color pixels 105R, 105G, and 105B. Therefore, it is possible to suppress the leakage current in the lateral direction from flowing through the common layer 128. As a result, since it is possible to suppress occurrence of unintended light emission between the pixels 105R, 105G, and 105B of different colors, it is possible to improve the display properties of the EL display device.

Further, the light emitting layer 132 is preferably separated by using the covering properties of an organic material in end portions of the common layer 128-2, the common layer 128-4, and the common layer 128-6. Accordingly, since a region where the light emitting device emits light is limited to a region where the pixel electrode 124 is arranged, it is possible to further suppress generation of unintended light emission.

In addition, although not shown in FIG. 2, the common layers 128 and 134 and the counter electrode 136 also extend along the direction Y and are separated in the direction X, similar to the light emitting layer 132. That is, the common layers 128 and 134 and the counter electrode 136 have regions extending along the direction Y on the pixel electrodes 124 adjacent to each other in the direction Y and regions extending along the direction Y between the two-pixel electrodes 124 adjacent to each other in the direction X. The organic layer 160 and the counter electrode 136 may be connected to each other in a region extending along the direction Y in the peripheral region 103. For example, in the common layers 128-1 to 128-7, regions extending along the direction Y may be separated from each other in the display region 102, and regions extending along the direction Y may be connected to each other in the peripheral region 103. For example, in the counter electrodes 136-1 to 136-7, regions extending along the direction Y may be separated from each other in the display region 102, and regions extending along the direction Y may be connected to each other in the peripheral region 103. Since the counter electrodes 136-1 to 136-7 are connected to each other in the peripheral region 103, wiring resistance in the counter electrodes 136-1 to 136-7 can be lowered.

In the present embodiment, although an example in which all of the organic layers 160 and the counter electrode 136 extend along the direction Y and are separated in the direction X is shown, an embodiment of the present invention is not limited thereto. The common layer 128 causes the lateral leakage current to flow. Therefore, it is sufficient that at least the common layer 128 extends along the direction Y and is separated in the direction X. The common layer 134 and the counter electrode 136 may be arranged continuously over the entire display region 102. If at least the common layer 128 extends along the direction Y and is separated in the direction X, the leakage current in the lateral direction can be suppressed from flowing in the common layer 128.

### [Method for Manufacturing Display Device]

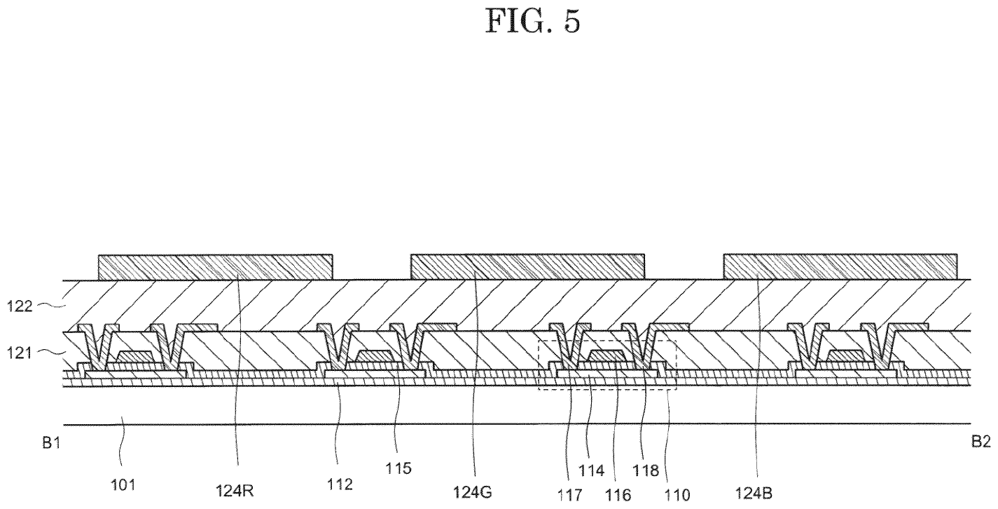

Next, a method for manufacturing the display device 100 will be described with reference to FIG. 5 to FIG. 11. In FIG. 5 to FIG. 11, methods of manufacturing a configuration corresponding to a cross-sectional view along the line B1-B2 shown in FIG. 2 will be described unless otherwise specified.

In FIG. 5 to FIG. 11, the transistor 110 constituting a pixel circuit is arranged on the substrate 101. In addition, a known method for manufacturing a transistor may be applied to a method for manufacturing the pixel circuit formed on the substrate 101, and thus a detailed description thereof will be omitted. The interlayer insulating film 121 including at least one of silicon oxide and silicon nitride is formed on the transistor 110. The source electrodes or the drain electrodes 117 and 118 are formed on the interlayer insulating film 121. The insulating film 122 is formed on the interlayer insulating film 121. The insulating film 122 functions as a planarization film. The insulating film 122 is made of an organic resin material. A known organic resin material such as polyimide-based, polyamide-based, acrylic-based, epoxy-based, or siloxane-based can be used as the organic resin material. It is possible to reduce unevenness of the transistor by providing the insulating film 122 on the transistor 110 or the interlayer insulating film 121. A contact hole is formed in the insulating film 122 to expose a portion of the source electrodes or the drain electrodes 117 and 118. The contact hole is for connecting the pixel electrode 124 to be formed in the next step and the source electrode or the drain electrode 117.

FIG. 5 is a diagram for explaining steps for forming the insulating film 122 and the pixel electrodes 124R, 124G, and 124B. The pixel electrodes 124R, 124G, and 124B are formed by a vapor deposition method using a metal mask. Each of the pixel electrodes 124R, 124G, and 124B is electrically connected to the source electrode or the drain electrode 117 connected to the transistor 110 via a contact hole arranged in the insulating film 122. In the present embodiment, the pixel electrodes 124R, 124G, and 124B function as anodes. A film thickness of the pixel electrode 124 is preferably, for example, 60 nm or more and 350 nm or less. In the present embodiment, the pixel electrodes 124R, 124G, and 124B are formed in a three-layer structure of a lower layer ITO, Ag, and an upper layer ITO. In this case, in the case where the pixel electrode 124 has the three-layer structure, for example, a thickness of the lower layer ITO is set to 5 nm or more and 100 nm or less, a thickness of Ag is set to 50 nm or more and 200 nm or less, and a thickness of the upper layer ITO is set to 5 nm or more and 50 nm or less. Combination of the material of a transparent conductive layer and a metal film in the pixel electrode 124 is not limited to the above.

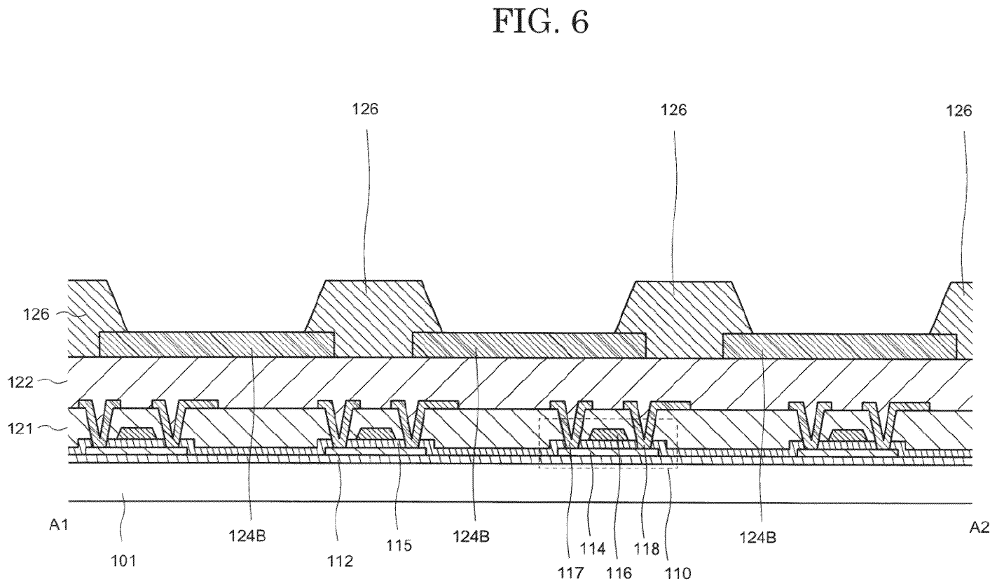

FIG. 6 is a diagram showing steps for forming the plurality of organic insulating layers 126. FIG. 6 is a cross-sectional view along the line A1-A2 shown in FIG. 2. As shown in FIG. 6, the organic insulating layer 126 is arranged between the pixel electrodes 124 adjacent to each other in the direction Y. The organic insulating layer 126 is arranged so as to cover the end portions of the adjacent pixel electrodes 124. The organic insulating layer 126 is made of an organic resin material. In addition, the organic insulating layer 126 is not formed between the pixel electrode 124R and the pixel electrode 124G, between the pixel electrode 124G and the pixel electrode 124B, and between the pixel electrode 124B and the pixel electrode 124R. A known organic resin material such as polyimide-based, polyamide-based, acrylic-based, epoxy-based, or siloxane-based can be used as the organic resin material. The common layers 128 and 134 and the light emitting layer 132 to be formed later can be formed without being separated by the pixel electrodes 124 by providing the organic insulating layer 126 between the pixel electrodes 124 adjacent to each other in the direction Y.

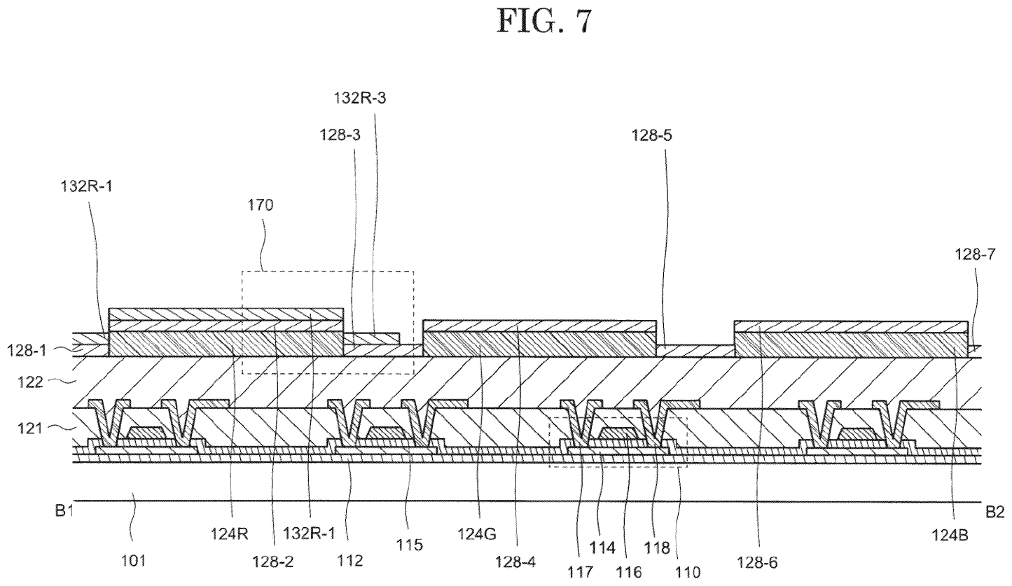

FIG. 7 is a diagram showing steps for forming the common layer 128 and the light emitting layer 132R. The common layers 128-1 to 128-7 are formed on the pixel electrodes 124R, 124G, and 124B. The common layers 128-1 to 128-7 include at least one of a hole transport layer and a hole injection layer. Known materials may be used as the hole transport layer and the hole injection layer as appropriate. In the case where the common layer 128 is formed on the pixel electrode 124 by the vapor deposition method, an overhang of the common layer 128 occurs when the common layer 128 is deposited on the pixel electrode 124. Since an overhanging portion has an eave structure, the common layer 128 is less likely to be attached to the side surface of the pixel electrode 124, and the common layer 128 is more likely to be cut off. As a result, the common layer 128 can be separated at the upper end portion of the pixel electrode 124.

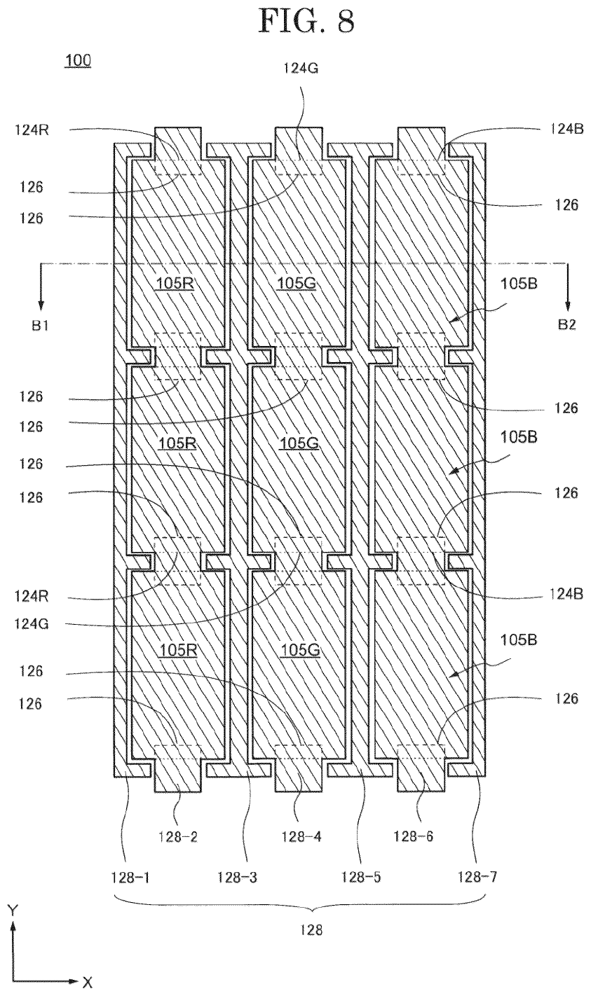

FIG. 8 is a plan view after the common layer 128 is formed. The common layers 128-1 to 128-7 are separated from each other in the direction X. Further, the common layers 128-1 to 128-7 extend in the direction Y. The common layers 128-2, 128-4, and 128-6 overlap the pixel electrode 124 and the organic insulating layer 126. The common layers 128-1, 128-3, 128-5, and 128-7 do not overlap the pixel electrode 124.

Next, the light emitting layer 132R is formed on the common layers 128-1 to 128-3. In the case where the light emitting layer 132R is formed on the common layer 128 by the vapor deposition method, an overhang of the light emitting layer 132R occurs when the light emitting layer 132R is deposited on the common layer 128-2. As a result, the light emitting layer 132R is less likely to be attached to side surfaces of the common layer 128-2 and the pixel electrode 124R, and the light emitting layer 132R is more likely to be cut off. As a result, the light emitting layer 132R can be separated at an upper end portion of the common layer 128-2. Thus, the light emitting layers 132R-1 to 132R-3 are formed.

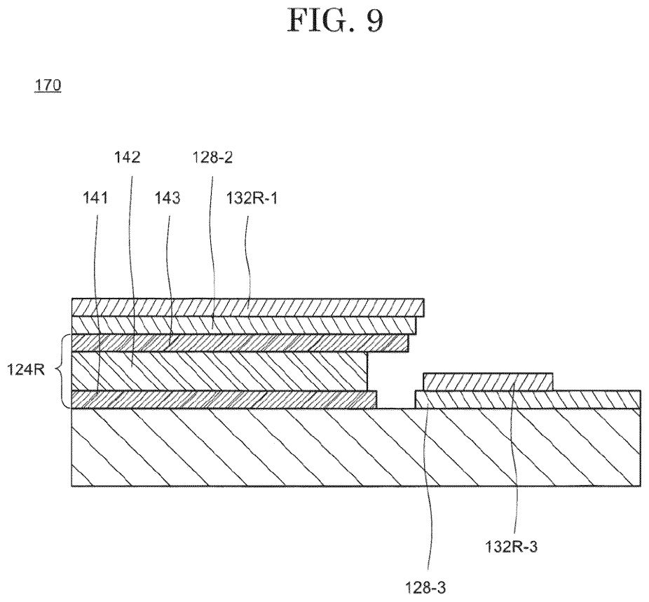

FIG. 9 is an enlarged view of a region 170 shown in FIG. 7. In FIG. 9, the pixel electrode 124 has a three-layer structure including a transparent conductive layer 141, a metal layer 142, and a transparent conductive layer 143. In addition, in the case where the pixel electrode 124 has a structure in which the transparent conductive layers 141 and 143 sandwich the metal layer 142, the transparent conductive layers 141 and 143 may protrude more than an end portion of the metal layer 142. Since an end portion of the transparent conductive layer 143 has an eave structure, the common layer 128 is less likely to be attached to the side surface of the pixel electrode 124, and the common layer 128 is more likely to be cut off. As a result, the common layer 128 can be separated at the end portion of the transparent conductive layer 143. As described above, it is possible to reliably cut the common layer 128 at the upper end portion of the pixel electrode 124 by configuring the pixel electrode 124 to have a three-layer structure. Similarly, in the case where the light emitting layer 132R is formed on the common layer 128, it is possible to reliably cut the light emitting layer 132R at the upper end portion of the common layer 128-2.

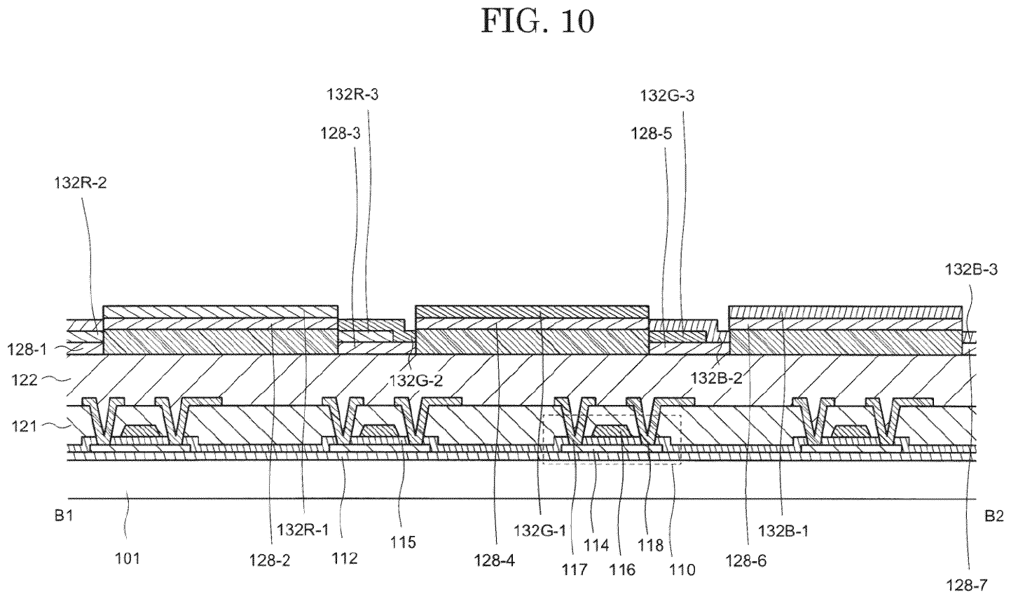

FIG. 10 is a diagram for explaining a step of forming light emitting layers 132G and 132B. A method for forming the light emitting layers 132G and 132B is the same as the method for forming the light emitting layer 132R. The light emitting layer 132G is formed on the common layers 128-3 to 128-5 by the vapor deposition method. The light emitting layers 132G-1 to 132G-3 are formed by separating the light emitting layer 132G at an end portion of the common layer 128-4. Next, the light emitting layer 132B is formed on the common layers 128-5 to 128-7 by the vapor deposition method. The light emitting layers 132B-1 to 132B-3 are formed by separating the light emitting layer 132B at an end portion of the common layer 128-6.

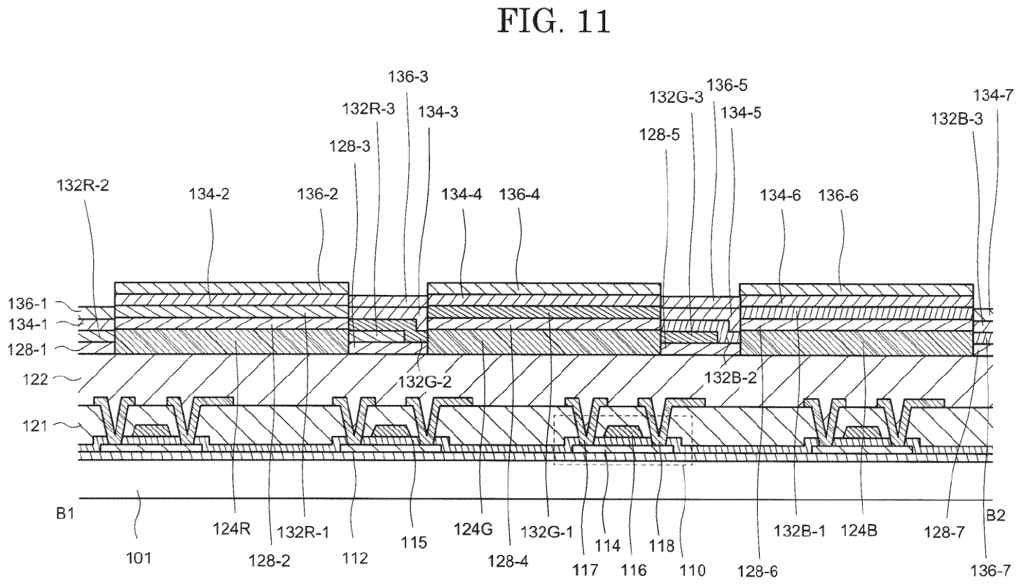

FIG. 11 is a diagram showing steps for forming the common layer 134 and the counter electrode 136. The common layers 134-1 to 134-7 are formed on the light emitting layers 132R, 132G, and 132B. The common layers 134-1 to 134-7 include at least one of an electron transport layer and an electron injection layer. Known materials may be used as the electron transport layer and the electron injection layer as appropriate. When the common layer 134 is formed on the light emitting layers 132R, 132G, and 132B by the vapor deposition method, the common layers 134-1 to 134-7 are formed by separating the common layer 134 at end portions of the light emitting layer 132R-1, the light emitting layer 132G-1, and the light emitting layer 132B-1. In addition, a plan view after the common layer 134 is formed is the same as that in FIG. 8, and thus illustration thereof is omitted.

Next, the counter electrode 136 is formed on the common layer 134. A counter electrode 136 may be formed of a light transmitting material as appropriate. When the counter electrode 136 is formed on the common layer 134, the counter electrodes 136-1 to 136-7 are formed by separating the counter electrodes 136 at end portions of the common layers 134-2, 134-4, and 134-6. In addition, a plan view after the counter electrode 136 is formed is the same as that in FIG. 8, and thus illustration thereof is omitted.

Next, the sealing film 150 is formed on the counter electrode 136. The sealing film 150 is formed in the order of the inorganic insulating film 151, the organic insulating film 152, and the inorganic insulating film 153. The inorganic insulating film 151 is preferably not separated on the counter electrode 136. A film thickness of the inorganic insulating film 151 is preferably a film thickness that reduces unevenness formed by the light emitting device 130. The thickness of the inorganic insulating film 151 may be larger than a thickness of the inorganic insulating film 153.

Through the above steps, the display device 100 shown in FIG. 2 to FIG. 4 can be manufactured.

According to a method for manufacturing the display device 100 according to an embodiment of the present disclosure, the common layers 128 are formed separately for pixels 105R, 105G, and 105B having different colors of light emission, and the common layer 128 is continuously formed for a plurality of pixels 105R having the same colors of light emission. As a result, even if high voltages are generated in the pixels 105R and 105G adjacent to the pixel 105B having a high light emission initialization voltage, it is possible to suppress a lateral leakage current from flowing. Therefore, it is possible to prevent the light emitting layers 132R and 132G from emitting light between the pixel 105G and the pixel 105B and between the pixel 105R and the pixel 105B. As a result, it is possible to suppress the occurrence of unintended light emission in the light emitting layer 132R and the light emitting layer 132G.

In the present embodiment, the light emitting layer 132G is formed after the light emitting layer 132R is formed. The forming order of the light emitting layers 132R, 132G, and 132B is not limited.

In FIG. 2 and FIG. 8, although the common layer 128-1 and the common layer 128-2 are separated from each other, and the common layer 128-2 and the common layer 128-3 are separated from each other, an embodiment of the present invention is not limited thereto. The common layer 128-2 may be connected to the common layer 128-1 or may be connected to the common layer 128-3 in a region adjacent to the organic insulating layer 126. Since a side surface of the organic insulating layer 126 is gently inclined, the common layers 128-1, 128-2, and 128-3 may not be separated in a region adjacent to the organic insulating layer 126. Even if the common layers 128-1 to 128-3 are connected, a lateral leakage current can be suppressed if the common layer 128 is separated between at least two pixel electrodes 124 adjacent to each other in the direction X.

### Second Embodiment

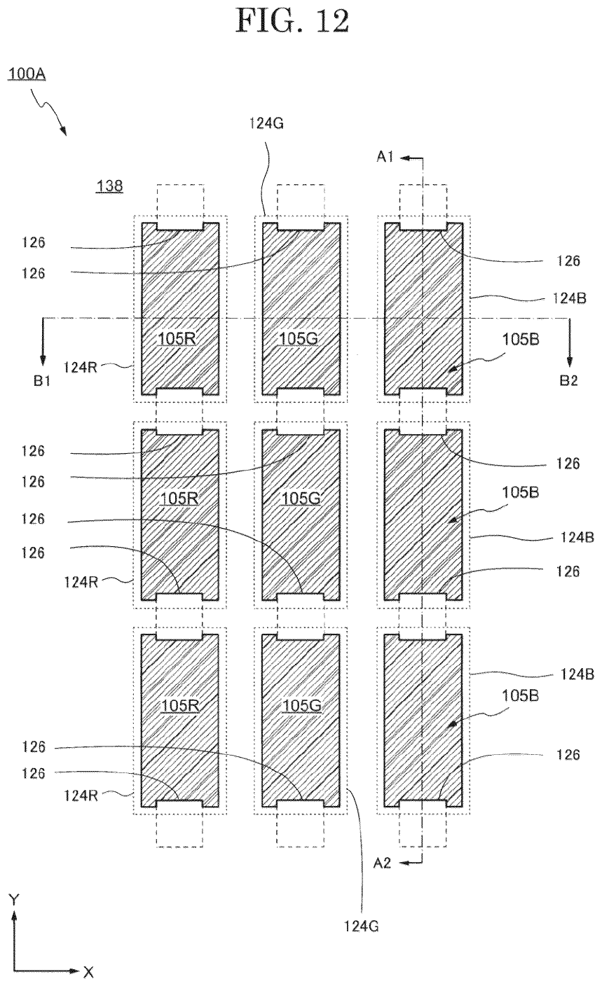

In this embodiment, a display device 100A having a configuration partially differing from the display device 100 according to the first embodiment will be described with reference to FIG. 12 to FIG. 14. In addition, description of the same configuration as in the first embodiment will be omitted as appropriate.

FIG. 12 is a plan view of the display device 100A according to an embodiment of the present disclosure. In FIG. 12, a planar layout of the organic layer 160 including the light emitting layer 132 is the same as that in FIG. 2 and FIG. 8, and thus illustration thereof is omitted.

As shown in FIG. 12, an inorganic insulating layer 138 is arranged on the pixel electrodes 124R, 124G, and 124B and the organic insulating layer 126. The inorganic insulating layer 138 is arranged so as to cover peripheral portions of the pixel electrodes 124R, 124G, and 124B. In other words, the inorganic insulating layer 138 is arranged with an opening so as to expose the pixel electrode 124R. The inorganic insulating layer 138 is arranged so as to overlap the organic insulating layer 126. The inorganic insulating layer 138 is formed of, for example, a silicon nitride film. A thickness of the inorganic insulating layers 138 is, for example, 50 nm or more and 500 nm or less.

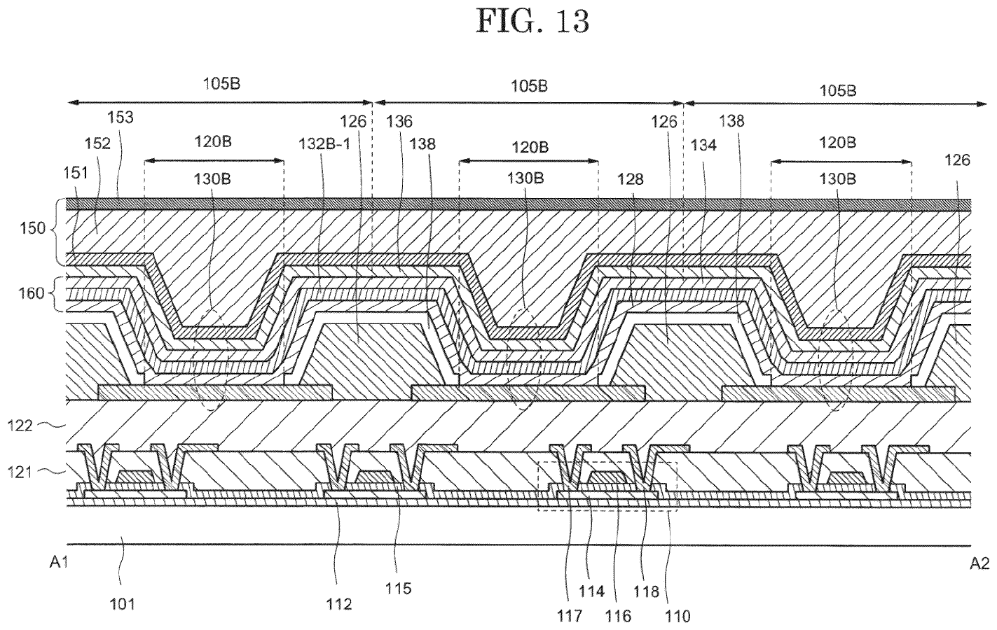

FIG. 13 is a cross-sectional view along a line A1-A2 shown in FIG. 12. As shown in FIG. 13, the inorganic insulating layer 138 covers the organic insulating layer 126. Accordingly, the organic layer 160 is arranged on the pixel electrode 124 and the inorganic insulating layer 138. In the opening of the inorganic insulating layer 138, the pixel electrode 124 and the common layer 128 are in contact with each other. The opening of the inorganic insulating layer 138 serves as a light emitting region of the light emitting device 130.

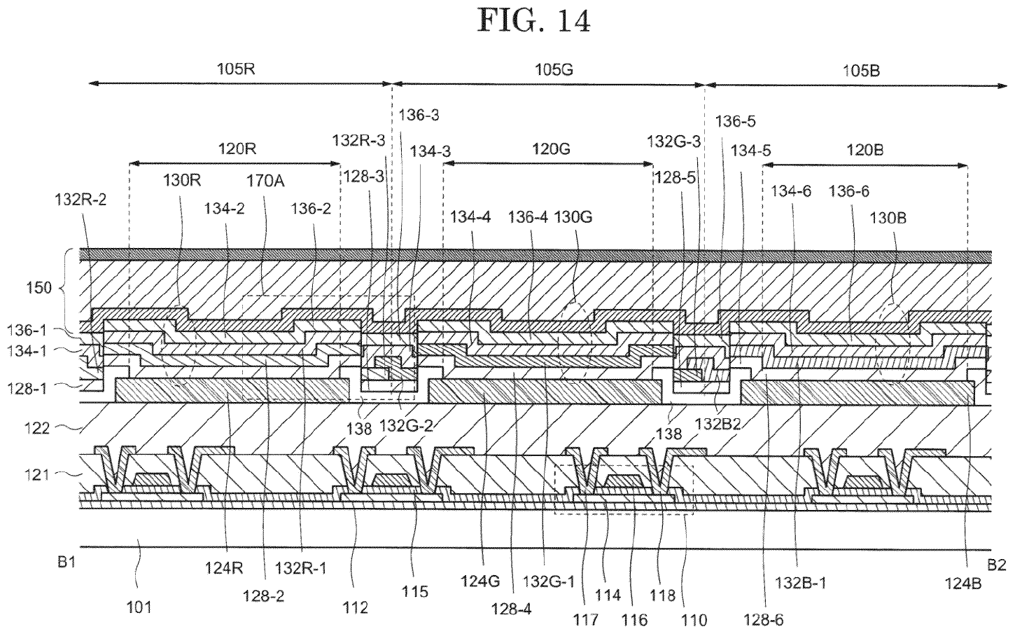

FIG. 14 is a cross-sectional view along a line B1-B2 shown in FIG. 12. As shown in FIG. 14, the inorganic insulating layer 138 covers the peripheral portions of the pixel electrodes 124R, 124G, and 124B. The common layer 128 is arranged on the pixel electrodes 124R, 124G, and 124B and the inorganic insulating layer 138. A film thickness of the pixel electrode 124 is larger than a film thickness of the common layer 128. In addition, the inorganic insulating layer 138 is arranged on the side surface of the pixel electrode 124.

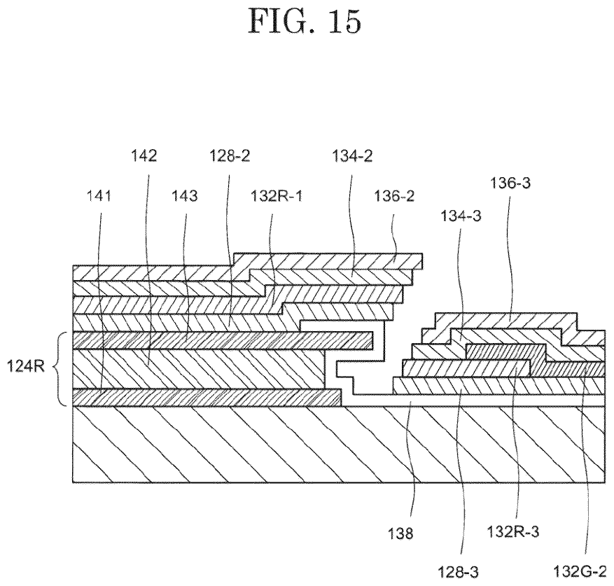

FIG. 15 is an enlarged view of a region 170A shown in FIG. 14. Also in FIG. 15, the pixel electrode 124 has a three-layer structure including the transparent conductive layer 141, the metal layer 142, and the transparent conductive layer 143. In addition, in the case where the pixel electrode 124 has a structure in which the transparent conductive layers 141 and 143 sandwich the metal layer 142, the transparent conductive layers 141 and 143 may protrude more than an end portion of the metal layer 142. The inorganic insulating layer 138 is formed by, for example, a sputtering method. Therefore, the inorganic insulating layer 138 is also formed on side surfaces of the transparent conductive layer 141, the metal layer 142, and the transparent conductive layer 143. At an end portion of the pixel electrode 124, a thickness of the inorganic insulating layer 138 is added to the thickness of the pixel electrode 124. Therefore, when the common layer 128 is formed on the pixel electrode 124 and the inorganic insulating layer 138 by the vapor deposition method, an overhang is more likely to occur at an end portion of the inorganic insulating layer 138. Since the overhanging portion has an eave structure, the common layer 128 is less likely to be attached to a side surface of the inorganic insulating layer 138, and the common layer 128 is more likely to be stepped. As a result, the common layer 128 can be separated at the upper end portion of the pixel electrode 124.

Further, the inorganic insulating layer 138 covers the side surface of the pixel electrode 124. As a result, it is possible to prevent the pixel electrode 124 from being electrically connected to the organic layer 160 arranged between the two adjacent pixel electrodes 124.

### Third Embodiment

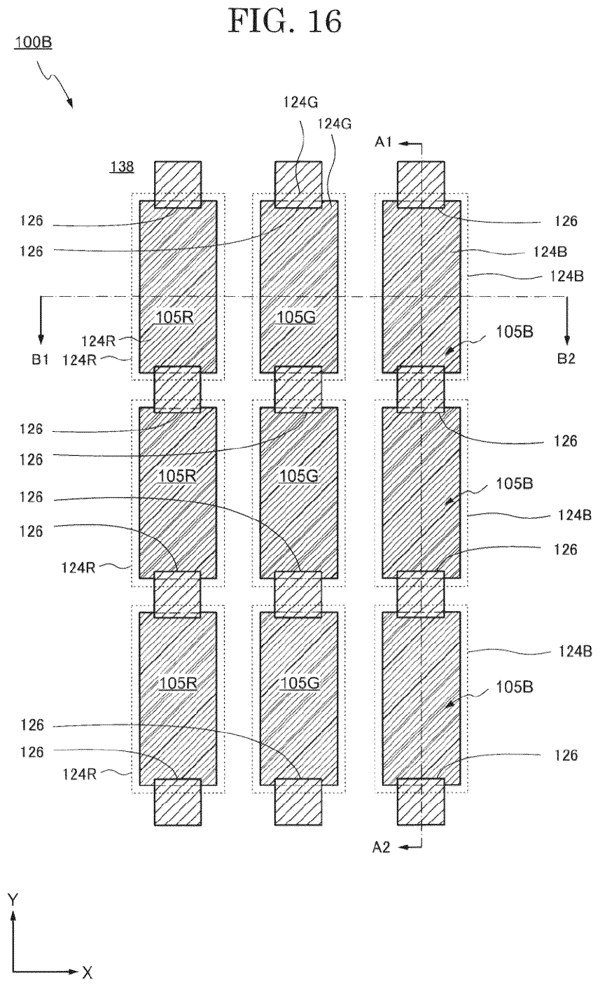

In this embodiment, a display device 100B having a configuration partially differing from the display device 100A according to the second embodiment will be described with reference to FIG. 15 to FIG. 16. In addition, description of the same configuration as in the previous embodiment will be omitted as appropriate.

FIG. 16 is a plan view of the display device 100B according to an embodiment of the present disclosure. In FIG. 16, a planar layout of the organic layer 160 including the light emitting layer 132 is the same as that in FIG. 2 and FIG. 8, and thus illustration thereof is omitted. In the present embodiment, a stacking order of the organic insulating layer 126 and the inorganic insulating layer 138 is different.

As shown in FIG. 16, the inorganic insulating layer 138 is arranged on the pixel electrodes 124R, 124G, and 124B. In addition, the organic insulating layer 126 is arranged on the pixel electrodes 124R, 124G, and 124B and the inorganic insulating layer 138. The inorganic insulating layer 138 is arranged so as to cover the peripheral portions of the pixel electrodes 124R, 124G, and 124B. In other words, the inorganic insulating layer 138 is arranged with an opening so as to expose the pixel electrode 124R. The inorganic insulating layer 138 is arranged so as to overlap the organic insulating layer 126. The inorganic insulating layer 138 is formed of, for example, a silicon nitride film. A thickness of the inorganic insulating layer 138 is, for example, 50 nm or more and 500 nm or less.

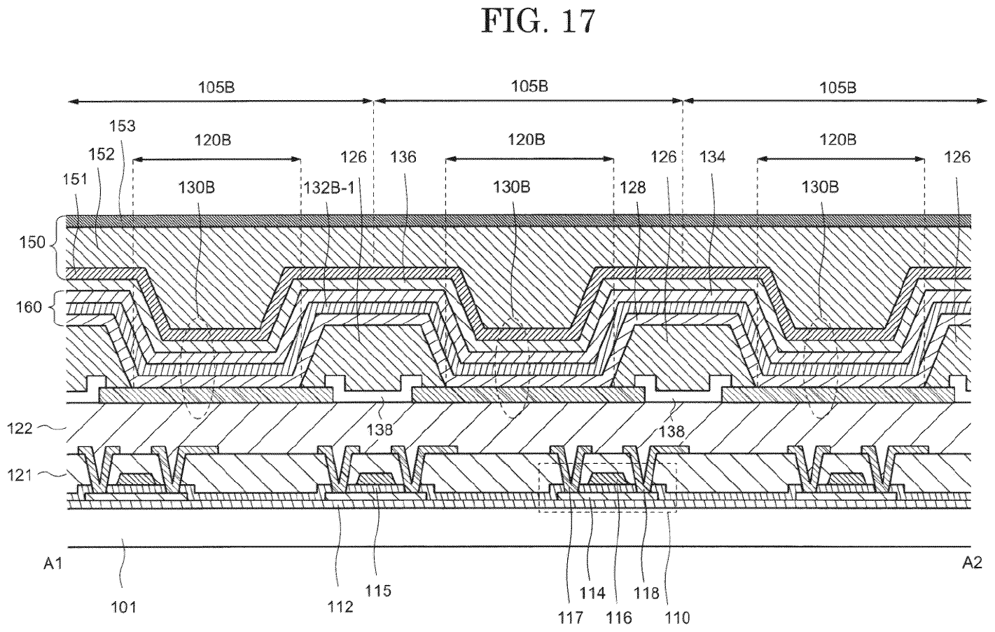

FIG. 17 is a cross-sectional view along a line A1-A2 shown in FIG. 16. As shown in FIG. 17, the inorganic insulating layers 138 cover the peripheral portions of the pixel electrodes 124R, 124G, and 124B. The common layer 128 is arranged on the pixel electrodes 124R, 124G, and 124B and the organic insulating layer 126. A cross-sectional view along a line B1-B2 shown in FIG. 16 is the same as that of FIG. 14, and thus detailed explanation thereof is omitted.

Also in the present embodiment, the inorganic insulating layer 138 covers the side surface of the pixel electrode 124. As a result, it is possible to prevent the pixel electrode 124 from being electrically connected to the organic layer 160 arranged between the two adjacent pixel electrodes 124.

### Fourth Embodiment

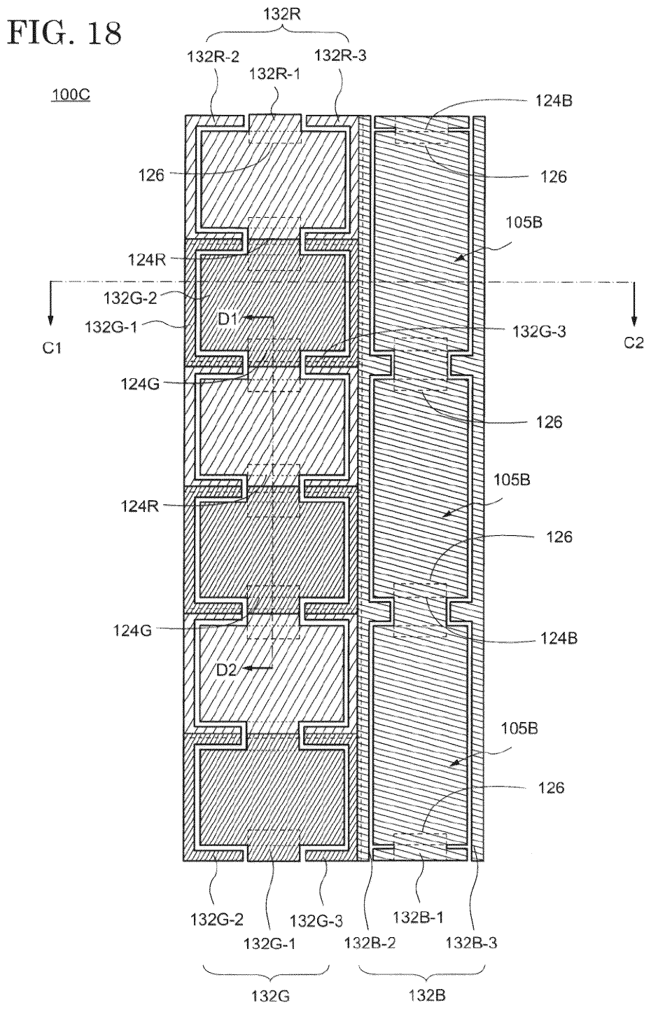

In this embodiment, a display device 100C in which an arrangement of the pixels 105R, 105G, and 105B differs partially to the display devices 100, 100A, and 100B shown in the previous embodiment will be described with reference to FIG. 18 to FIG. 20. In addition, description of the same configuration as in the previous embodiment will be omitted as appropriate.

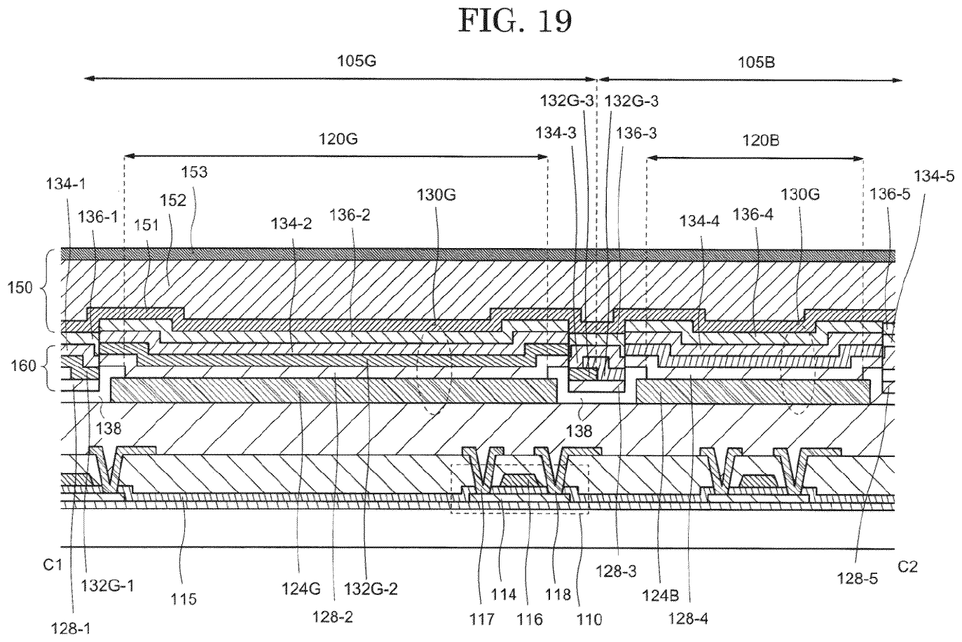

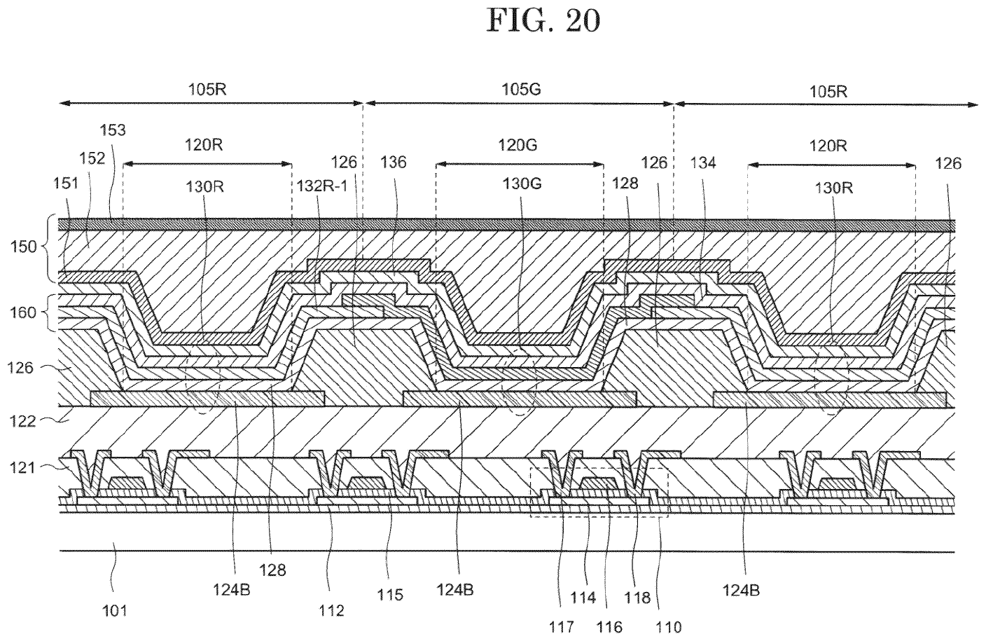

FIG. 18 is an enlarged view of a pixel layout when the display device 100C is viewed in a plan view, and FIG. 19 is a cross-sectional view when the pixel layout shown in FIG. 18 is cut along a line C1-C2. FIG. 20 is a cross-sectional view of the pixel layout shown in FIG. 18 along a line D1-D2.

In FIG. 18, the pixels 105R and the pixels 105G are alternately arranged in the direction Y. The pixels 105B are arranged side by side in the direction Y. The pixels 105R are arranged adjacent to the pixels 105B in the direction X. Further, the pixels 105G are arranged adjacent to the pixels 105B in the direction X.

The organic insulating layer 126 is arranged so as to cover the end portions of the pixel electrodes 124R and the end portions of the pixel electrodes 124G, which are adjacent to each other in the direction Y. In addition, the organic insulating layer 126 is arranged so as to cover the end portions of the two pixel electrodes 124B and the end portions of the pixel electrodes 124B adjacent to each other in the direction Y. The organic insulating layer 126 is not arranged between the two pixel electrodes 124R adjacent to each other in the direction X and the pixel electrodes 124B. Further, the organic insulating layer 126 is not arranged between the two pixel electrodes 124G and the pixel electrode 124B which are adjacent to each other in the direction X.

The light emitting layer 132R has the light emitting layers 132R-1 to 132R-3. Each of the light emitting layers 132R-1 to 132R-3 is separated. The light emitting layer 132R-1 is arranged on the pixel electrode 124R. The light emitting layer 132R-2 is arranged adjacent to the pixel electrode 124R. The light emitting layer 132R-3 is arranged between the pixel electrode 124R and the pixel electrode 124B. The light emitting layer 132G has the light emitting layers 132G-1 to 132G-3. The light emitting layer 132G-1 is arranged on the pixel electrode 124G. The light emitting layer 132G-2 is arranged adjacent to the pixel electrode 124G. The light emitting layer 132G-3 is arranged between the pixel electrode 124G and the pixel electrode 124B. The light emitting layers 132B-1 to 132B-3 are separated from each other. In addition, the light emitting layer 132B-1 is arranged on the plurality of pixel electrodes 124B adjacent to each other in the direction Y. The light emitting layer 132B-2 is arranged between the pixel electrodes 124R and 124G and the pixel electrode 124B. The light emitting layer 132B-3 is arranged adjacent to the pixel electrode 124B. The light emitting layers 132R-2 and 132G-3 overlap the light emitting layer 132B-3 (not shown). Further, the light emitting layers 132R-3 and 132G-3 overlap the light emitting layer 132B-2. In addition, the light emitting layer 132R-1 overlaps the light emitting layer 132G-1 on the organic insulating layer 126.

In FIG. 19, a cross-sectional view in the case where the pixel 105G and the pixel 105B are adjacently shown is substantially the same as that in FIG. 14, and therefore, for a detailed description, the description of FIG. 14 may be referred to.

FIG. 20 shows a case where the pixel 105R and the pixel 105G are adjacent to each other. In FIG. 20, the light emitting layer 132R-1 and the light emitting layer 132G-1 overlap each other on the organic insulating layer 126.

The light emitting device 130B has a higher emission initialization voltage than the light emitting device 130R and the light emitting device 130G. Therefore, the light emitting device 130B may cause unintentional light emission by the light emitting devices 130R and 130G in a region where the light emitting device 130B and the light emitting devices 130R and 130G are adjacent to each other.

In the present embodiment, the light emitting layer 132 is separated at the end portion of the pixel electrode 124. Therefore, a region where the light emitting layer 132B and the light emitting layers 132R and 132G overlap each other is less susceptible to a voltage applied to the pixel electrode 124. Therefore, it is possible to suppress a lateral leakage current from flowing, and thus it is possible to improve display quality.

In addition, a light emission initialization voltage of the light emitting device 130R and a light emission initialization voltage of the light emitting device 130G are approximately the same. Therefore, even if either the light emitting device 130R or the light emitting device 130G emits light, an effect of a lateral leakage current from the light emitting layer 132R-1 or the light emitting layer 132G-1 is small. Therefore, there may be a region where the light emitting layer 132R-1 and the light emitting layer 132G-1 overlap each other on the organic insulating layer 126.

### Fifth Embodiment

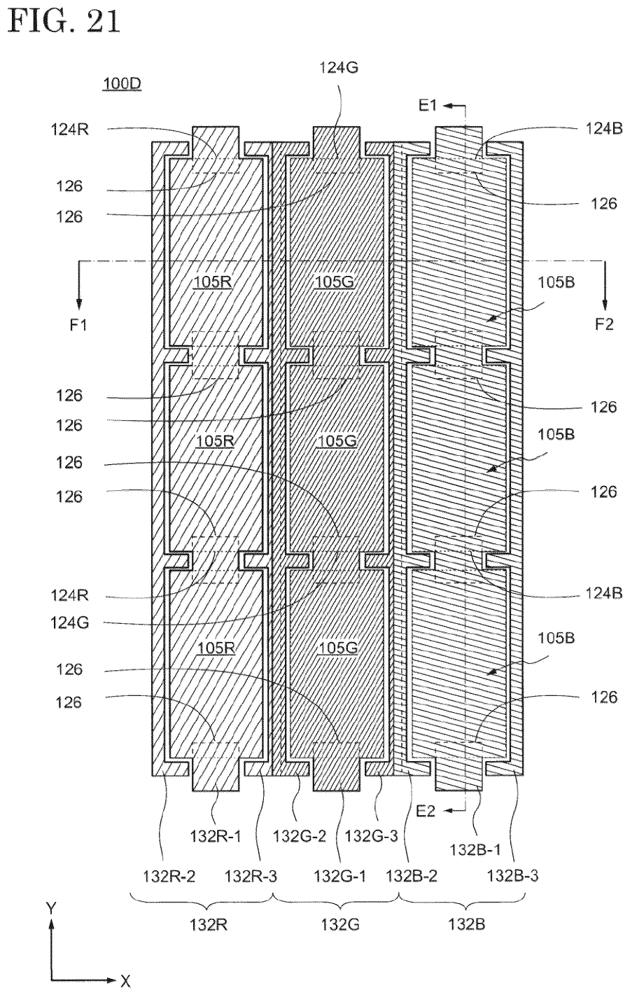

In this embodiment, a display device 100D in which a stacking order of the counter electrode 136 is reversed from the pixel electrode 124 in the display devices 100 and 100A to 100C according to the previous embodiment will be described with reference to FIG. 21 to FIG. 23.

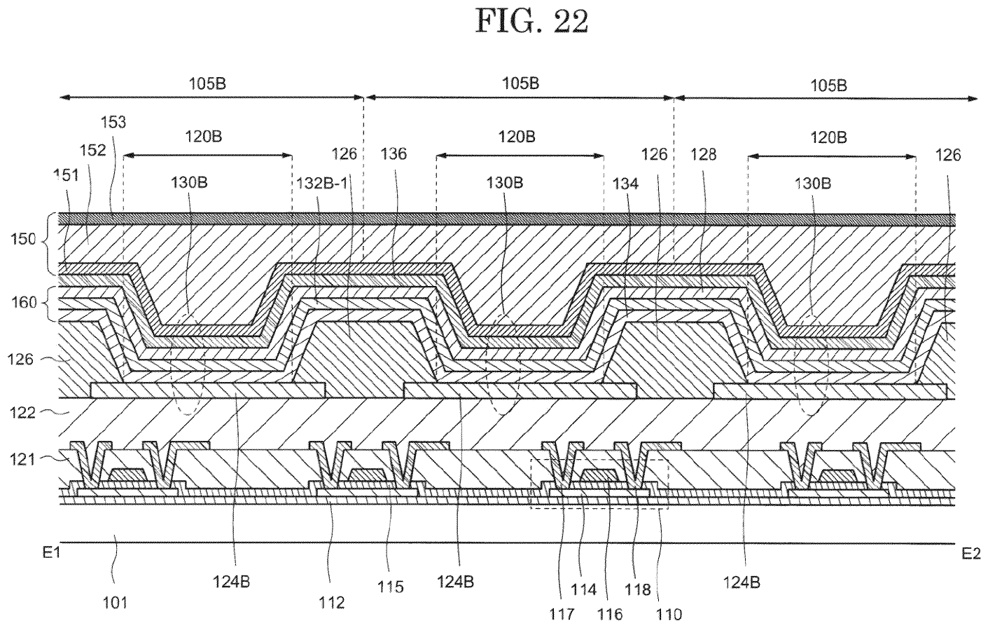

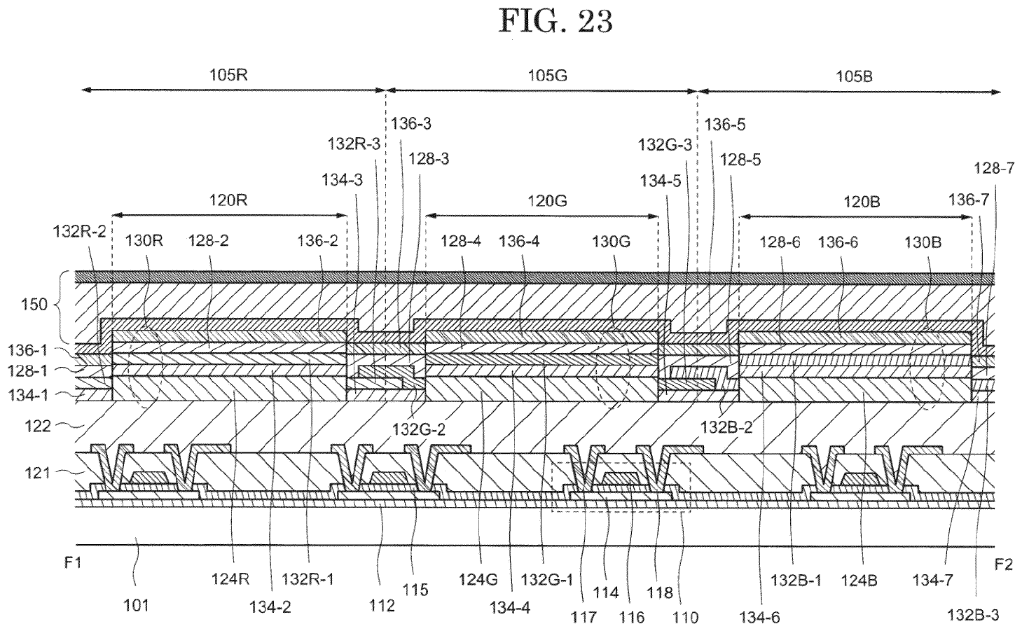

FIG. 21 is an enlarged view of a pixel layout when the display device 100 is viewed in a plan view, and FIG. 22 is a cross-sectional view when the pixel layout shown in FIG. 21 is along a line E1-E2. FIG. 23 is a cross-sectional view of the pixel layout shown in FIG. 21 along a line F1-F2.

The display device 100D differs from the display device 100 in that the pixel electrodes 124R, 124G, and 124B function as cathodes and the counter electrode 136 functions as an anode. In FIG. 21, a region surrounded by a short-wave line is a region in which the pixel electrodes 136R, 136G, and 136B are arranged. In the case where the pixel electrodes 124R, 124G, and 124B are used as the cathodes, the counter electrode 136 described in the first embodiment may be used. In addition, in the case where the counter electrode 136 is used as the anode, the material of the pixel electrode 124 described in the first embodiment may be used. In addition, although not shown in FIG. 21 to FIG. 23, each of the pixel electrodes 124R, 124G, and 124B is electrically connected to the transistor 110 included in the pixel circuit.

In FIG. 22 and FIG. 23, the common layer 134 arranged between the pixel electrodes 124R, 124G, and 124B and the light emitting layers 132R, 132G, and 132B includes at least one of an electron transporting layer and an electron injecting layer. Further, the common layer 128 arranged between the counter electrode 136 and the light emitting layers 132R, 132G, and 132B includes at least one of a hole transporting layer and a hole injecting layer.

The pixel electrodes 124R, 124G, and 124B are arranged on the insulating film 122. The common layer 134 is arranged on the pixel electrodes 124R, 124G, and 124B. In FIG. 22, the common layer 134 is separated by upper end portions of the pixel electrodes 124R, 136G, and 136B. Therefore, the common layer 134 includes the common layers 134-1 to 134-7. The common layer 134-2 is arranged on the pixel electrode 124R, the common layer 134-4 is arranged on the pixel electrode 124G, and the common layer 134-6 is arranged on the pixel electrode 124B. The common layer 134-1 is arranged adjacent to the pixel electrode 124R in the direction X. In addition, the common layer 134-3 is arranged between the pixel electrode 124R and the pixel electrode 124G. The common layer 134-5 is arranged between the pixel electrode 124G and the pixel electrode 124B. In addition, the common layer 134-7 is arranged adjacent to the pixel electrode 124B in the direction X.

Here, a film thickness of the pixel electrode 124 is larger than a film thickness of the common layer 134. Therefore, when the common layer 134 is formed on the pixel electrode 124 by vapor deposition, the common layer 134 is less likely to be attached to the side surface of the pixel electrode 124. As a result, the common layer 134 can be separated at the upper end portion of the pixel electrode 124. The film thickness of the pixel electrode 124 is, for example, 60 nm or more and 350 nm or less. The thickness of the common layer 134 is, for example, 30 nm or more and 150 nm or less, and is less than the thickness of the pixel electrode 124.

The light emitting layers 132R, 132G, and 132B are separated by upper end portions of the common layers 134-2, 134-4, and 134-6, respectively. The light emitting layer 132R has the light emitting layers 132R-1 to 132R-3, the light emitting layer 132G has the light emitting layers 132G-1 to 132G-3, and the light emitting layer 132B has the light emitting layers 132B-1 to 132B-3. The common layer 128 is separated by the upper end portions of the light emitting layer 132R-1, 132G-1, and 132B-1. The common layer 128 has the common layers 128-1 to 128-7. The counter electrode 136 is separated by upper end portions of the common layers 128-2, 128-4, and 128-6, respectively. The counter electrode 136 includes counter electrodes 136-1 to 136-6.

In the display device 100D, in the light emitting device 130, the pixel electrode 124 is used as a cathode and the counter electrode 136 is used as an anode. Even in this case, at least the common layer 134 is separated so as to extend in the direction Y between the pixels 105R, 105G, and 105B of the different colors. Specifically, the common layer 134 is separated by using the covering property of an organic material in the end portion of the pixel electrode 124. As a result, the common layer 134 is separated between the pixels 105R, 105G, and 105B of different colors. Therefore, it is possible to suppress a leakage current in a lateral direction from flowing via the common layer 134. As a result, it is possible to suppress the occurrence of unintended light emission between pixels 105R, 105G, and 105B of different colors. Therefore, it is possible to improve the display properties of the EL display device.

FIG. 22, FIG. 23, and the configuration described above show an example in which a total thickness of the common layer 134 is smaller than that of the pixel electrode 124. Although not particularly shown, the common layer 134 includes an electron injection layer arranged in contact with the pixel electrode 124 and an electron transport layer stacked thereon. In this case, if a film thickness of the electron injection layer is smaller than the film thickness of the pixel electrode 124, the total thickness of the common layer 134 including the stack of the electron injection layer and the electron transport layer may exceed the pixel electrode 124. Of course, as described above, although it is desirable that the common layer 134 be divided over the entire layer, in the common layer 134, since a material having a relatively low resistance is used for the electron injection layer in order to improve the electron injection efficiency from the pixel electrode 124, a leakage current in the lateral direction can be reduced by dividing the layer by the upper end portion of the pixel electrode 124. In this configuration, the film thickness of the pixel electrode 124 is, for example, 60 nm or more and 350 nm or less. A thickness of the common layer 128 may be, for example, 100 nm or more and 150 nm or less, and a thickness of the electron injecting layer, which is less than the thickness of the pixel electrode 124 and is arranged in contact with the pixel electrode 124, may be, for example, 0.1 nm or more and 10 nm or less.

In addition, the configuration of the display device 100D according to the present embodiment can be applied to the configurations according to the display devices 100 and 100A to 100C according to the previous embodiment. That is, in the display devices 100 and 100A to 100C, the pixel electrode 124 may be used as a cathode, and the counter electrode 136 may be used as an anode. In this case, the common layer 134 arranged between the pixel electrode 124 and the light emitting layer 132 may include at least one of an electron transport layer and an electron injection layer. The common layer 128 arranged between the counter electrode 136 and the light emitting layer 132 may include at least one of a hole transport layer and a hole injection layer.

As described above, a display device according to an embodiment of the present invention can be applied to various forms. Therefore, based on the display devices 100 and 100A to 100D described as the embodiments and the modifications of the invention, those that the person skilled in the art appropriately adds, deletes or changes the designs of the constituent elements, or those that add, omit or change the conditions of the processes are also included in the scope of the present invention, as long as they have the gist of the present invention. In addition, the embodiments described above can be combined with each other within a range in which no technical inconsistency occurs.

In addition, the embodiments described above have been described mainly for a display device including an organic EL device as a display device, in which a leakage current in the organic layer 160 is suppressed. An embodiment of the present invention can be applied not only to a display device but also to an optical sensor device or the like configured by arranging an organic photodiode in which an organic layer is sandwiched between electrodes in a matrix form. Specifically, the present invention can be applied to an overlapping relationship at an end portion of an organic layer constituting an organic photodiode to be formed by coating.

In addition, it is to be understood that the present invention provides other operational effects that are different from the operational effects provided by the aspects of the embodiments described above, and those that are obvious from the description of the present specification or those that can be easily predicted by a person skilled in the art.

Within the scope of the present invention, those skilled in the art will appreciate that various changes and modifications can be made, and that such changes and modifications also fall within the scope of the present invention. For example, a person skilled in the art appropriately adds, deletes, or changes the design of the constituent elements, or adds, omits, or changes in conditions of the steps for each of the embodiments described above are included in the scope of the present invention as long as the present invention is provided.

What is claimed is:

1. A display device comprising:
a first pixel electrode arranged on an insulating surface;
a second pixel electrode spaced apart from the first pixel electrode in a first direction;
a third pixel electrode spaced apart from the first pixel electrode in a second direction intersecting the first direction;
an organic insulating layer overlapping a part of the first pixel electrode and a part of the second pixel electrode in the first direction;
a first common layer arranged on the first pixel electrode, the second pixel electrode, the third pixel electrode, and the organic insulating layer;
a first light emitting layer arranged on the first common layer and continuously arranged overlapping the first pixel electrode, the second pixel electrode, and the organic insulating layer;
a second light emitting layer arranged on the first pixel electrode and arranged overlapping the third light emitting layer; and
a counter electrode arranged on the first light emitting layer and the second light emitting layer,
wherein
the first common layer has a first region overlapping the first pixel electrode, a second region provided between the first pixel electrode and the third pixel electrode, and a third region overlapping the third pixel electrode, and
the second region is separated from each of the first region and third region.

2. The display device according to claim 1, wherein
the first light-emitting layer is separated between the first region and second region, and the second light-emitting layer is separated between the second region and third region.

3. The display device according to claim 1, wherein
the counter electrode is separated between the first region and the second region, and between the second region and the third region.

4. The display device according to claim 1, wherein
a thickness of the first pixel electrode is greater than a thickness of the first common layer.

5. The display device according to claim 1, further comprising:
an inorganic insulating layer covering a periphery of the first pixel electrode, a periphery of the second pixel electrode and a periphery of the third pixel electrode, wherein
the inorganic insulating layer is provided above the organic insulating layer.

6. The display device according to claim 1, further comprising:
an inorganic insulating layer covering a periphery of the first pixel electrode, a periphery of the second pixel electrode and a periphery of the third pixel electrode, wherein
the inorganic insulating layer is provided below the organic insulating layer.

7. The display device according to claim 1, wherein
the first common layer has at least one of a hole transport layer and a hole injection layer, when the first pixel electrode, the second pixel electrode and the third pixel electrode are anodes.

8. The display device according to claim 1, wherein
the first common layer has at least one of an electron transport layer and an electron injection layer, when the first pixel electrode, the second pixel electrode and the third pixel electrode are cathodes.

9. The display device according to claim 1, further comprising:
a second common layer between the first emission layer and second emission layer and the counter electrode.

10. The display device according to claim 1, wherein
the first pixel electrode has a first conductive layer, a second conductive layer and a third conductive layer stacked in order from the insulating surface,
a thickness of the second conductive layer is thicker than a thickness of the first conductive layer and thicker than a thickness of the third conductive layer, and
an edge of the third conductive layer protrudes more than an edge of the second conductive layer in a cross-sectional view.

11. The display device according to claim 1, wherein
a shape of the organic insulating layer is rectangular in a plan view.
